(19) United States
(12) Patent Application Publication
(10) Pub. No.: US 2014/0056069 A1
(43) Pub. Date: Feb. 27, 2014

(54) NONVOLATILE MEMORY DEVICE HAVING NEAR/FAR MEMORY CELL GROUPINGS AND DATA PROCESSING METHOD

(71) Applicants: IL HAN PARK, SUWON-SI (KR); SEUNG-BUM KIM, HWASEONG-SI (KR); GOEUN JUNG, HWASEONG-SI (KR)

(72) Inventors: IL HAN PARK, SUWON-SI (KR); SEUNG-BUM KIM, HWASEONG-SI (KR); GOEUN JUNG, HWASEONG-SI (KR)

(21) Appl. No.: 13/935,596

(22) Filed: Jul. 5, 2013

(30) Foreign Application Priority Data
Aug. 21, 2012 (KR) 10-2012-0091482

(51) Int. Cl. G11C 16/04; G11C 16/24

(52) U.S. Cl. CPC G11C 16/0483; G11C 16/24
USPC 365/185.05; 365/185.25; 257/499

(57) ABSTRACT

A nonvolatile memory device includes; a memory cell array designating a first memory cell group including first memory cells connected with a word line and disposed less than a reference distance from a word line voltage source in a word line direction, and a second memory cell group including second memory cells connected to the word line and disposed more than the reference distance from the word line voltage source in the word line direction, and control logic configured during a data processing operation to provide a first word line voltage to a first target memory cell among the first memory cells, and a second word line voltage different from the first word line voltage to a second target memory cell among the second memory cells.

### CROSS-REFERENCE TO RELATED APPLICATIONS

A claim of priority under 35 U.S.C. §119 is made to Korean Patent Application No. 10-2012-0091482 filed Aug. 21, 2012, the subject matter of which is hereby incorporated by reference.

### BACKGROUND

The inventive concept relates nonvolatile memory devices and data processing methods.

Nonvolatile memory devices have become important components in contemporary computational platforms and consumer electronic devices. The ability of nonvolatile memory devices to retain stored data in the absence of applied power is a particularly desirable quality. Nonvolatile memory devices include the Read Only Memory (ROM), programmable ROM (PROM), electrically programmable ROM (EPROM), electrically erasable and programmable ROM (EEPROM)—including the so-called “flash memory”, phase-change RAM (PRAM), magnetic RAM (MRAM), resistive RAM (RRAM), ferroelectric RAM (FRAM), and the like.

Flash memory has been widely incorporated in many applications due to its relatively fast data access, low power consumption, and high data storage density. Flash memory currently comes in two principle types; NOR type and NAND type.

Contemporary semiconductor memory devices, including all forms of nonvolatile memory, include a vast number of individual memory cells. As is conventionally understood, the constituent memory cell array of a nonvolatile memory device is divided into a number of memory blocks, each memory block is sub-divided into a number of pages, where each page includes a number of memory cells. Such logical division of the numerous memory cells in a memory cell array is very useful during data access operations (e.g., read, program and erase) and general nonvolatile memory device management. For example, flash memory may perform erase operations on a block-by-block basis, while performing read/program operations on a page-by-page basis.

The memory cells of a memory cell array in a contemporary nonvolatile memory are generally laid out according to a matrix of intersecting “word lines” and “bit lines”. Certain control voltages (e.g., a program voltage, read voltage, verification voltage, erase voltage, precharge voltage, inhibit voltage, select voltage, etc.) are variously applied to one or more of the word lines and/or one or more of the bits lines of the memory cell array during each data access operation. Multiple timing considerations must be taken into account for the application of the control voltage(s) during the various operations performed by a nonvolatile memory device.

### SUMMARY

In one embodiment, the inventive concept provides a nonvolatile memory device comprising; a memory cell array designating a first memory cell group including first memory cells connected with a word line and disposed less than a reference distance from a word line voltage source in a word line direction, and a second memory cell group including second memory cells connected to the word line and disposed more than the reference distance from the word line voltage source in the word line direction, and control logic configured during a data processing operation to provide a first word line voltage to a first target memory cell among the first memory cells, and a second word line voltage different from the first word line voltage to a second target memory cell among the second memory cells.

In another embodiment, the inventive concept provides a nonvolatile memory device comprising; a memory cell array designating a first memory cell group including first memory cells connected with a word line and disposed less than a reference distance from a word line voltage source in a word line direction, and a second memory cell group including second memory cells connected to the word line and disposed more than the reference distance from the word line voltage source in the word line direction, a first bit line group connected with memory cells of the first memory cell group, and a second bit line group connected with memory cells of the second memory cell group, and control logic configured to provide a first precharge voltage to the first bit line group and a second precharge voltage having a level different from the first precharge voltage to the second bit line group during a data processing operation.

In another embodiment, the inventive concept provides a nonvolatile memory device comprising; a memory cell array designating a first memory cell group including first memory cells connected with a word line and disposed less than a reference distance from a word line voltage source in a word line direction, and a second memory cell group including second memory cells connected to the word line and disposed more than the reference distance from the word line voltage source in the word line direction, a first bit line group connected with memory cells of the first memory cell group, and a second bit line group connected with memory cells of the second memory cell group, a data input/output (I/O) unit connected with the first bit line group and the second bit line group, and control logic configured to control the data I/O unit during a data processing operation to define a first sensing time for the first bit line group and a second sensing time for the second bit line group, wherein the first and second sensing times are different.

In another embodiment, the inventive concept provides a nonvolatile memory device comprising; a memory cell array designating a first memory cell group including first memory cells connected with a word line and disposed less than a reference distance from a word line voltage source in a word line direction, and a second memory cell group including second memory cells connected to the word line and disposed more than the reference distance from the word line voltage source in the word line direction, at least one common source line driver connected with the memory cells in the first and second memory cell groups and configured to provide a common source line voltage, and control logic configured to control the at least one common source line (CSL) driver during a data processing operation to define a first CSL voltage provided to the first bit line group and a second CSL voltage provided to the second bit line group, wherein the first and second CSL voltages are different.

### BRIEF DESCRIPTION OF THE FIGURES

The above and other objects and features of the inventive concept along with its making and use may be readily understood by consideration of the following description with reference to the accompanying drawings.

FIG. 1 is a block diagram illustrating a nonvolatile memory device according to an embodiment of the inventive concept.

FIGS. 2A, 2B and 2C are diagrams illustrating threshold voltages when relatively near and far memory cells of the nonvolatile memory device of FIG. 1 are programmed.

FIG. 3 is a block diagram illustrating a nonvolatile memory device according to an embodiment of the inventive concept.

FIG. 4 is a timing diagram illustrating a program verification method that may be performed by a nonvolatile memory device according to an embodiment of the inventive concept.

FIG. 5 is a timing diagram illustrating a program verification method that may be performed by a nonvolatile memory device according to another embodiment of the inventive concept.

FIG. 6 is a block diagram illustrating a nonvolatile memory device according to another embodiment of the inventive concept.

FIG. 7 is a timing diagram illustrating a program verification method that may be performed the nonvolatile memory device of FIG. 6.

FIG. 8 is a block diagram illustrating a nonvolatile memory device according to still another embodiment of the inventive concept.

FIG. 9 is a diagram illustrating respective threshold voltage distributions for near and far memory cell groups with respect to the same program state.

FIG. 10 is a diagram illustrating a sequence of word line voltages that may be applied during a program operation applied to the nonvolatile memory device of FIG. 8.

FIG. 11 is a flow chart summarizing a data processing method for a nonvolatile memory device according to an embodiment of the inventive concept.

FIG. 12 is a diagram further illustrating the memory cell array of the memory device of FIG. 1 according to an embodiment of the inventive concept.

FIG. 13 is a top view of a portion of a memory block of FIG. 12 according to an embodiment of the inventive concept.

FIG. 14 is a perspective view taken along a line IV-IV' in FIG. 13.

FIG. 15 is a cross-sectional view taken along a line IV-IV' in FIG. 13.

FIG. 16 is an enlarged view illustrating one of the cell transistors in FIG. 15.

FIG. 17 is an equivalent circuit for the part EC noted in the top view of FIG. 13 according to an embodiment of the inventive concept.

FIG. 18 is a block diagram illustrating a memory card system that may incorporate a nonvolatile memory device according to an embodiment of the inventive concept.

FIG. 19 is a block diagram illustrating a solid state drive (SSD) system that may incorporate a memory device according to the inventive concept is applied.

FIG. 20 is a block diagram further illustrating the SSD controller of FIG. 19.

FIG. 21 is a block diagram illustrating an electronic device that may incorporate a memory system according to an embodiment of the inventive concept.

### DETAILED DESCRIPTION

Embodiments of the inventive concept will now be described in some additional detail with reference to the accompanying drawings. The inventive concept, however, may be embodied in various different forms, and should not be construed as being limited to only the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. Unless otherwise noted, like reference numbers and labels denote like or similar elements throughout the attached drawings and written description. In the drawings, the size(s) and relative size(s) of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

The term “selected bit line” or “selected bit lines” is used to indicate a particular bit line or particular bit lines connected with one or more cell transistor(s) to be programmed or to be read during a current operation from among a plurality of bit lines. The term “unselected bit line” or “unselected bit lines” is used to indicate a particular bit line or particular bit lines connected with one or more cell transistor(s) to be program-inhibited or read-inhibited during a current operation from among the plurality of bit lines.

The term “selected word line” is used to indicate a particular word line connected with a cell transistor to be programmed or to be read from among a plurality of word lines. The term “unselected word line” or “unselected word lines” is used to indicate a remaining word line or remaining word lines—other than the selected word line—from among the plurality of word lines.

The term “selected memory cell” or “selected memory cells” is used to designate memory cells to be programmed or to be read by a current operation from among a plurality of memory cells. The term “unselected memory cell” or “unselected memory cells” is used to indicate a remaining memory cell or remaining memory cells—other than the selected memory cell or selected memory cells—from among the plurality of memory cells.

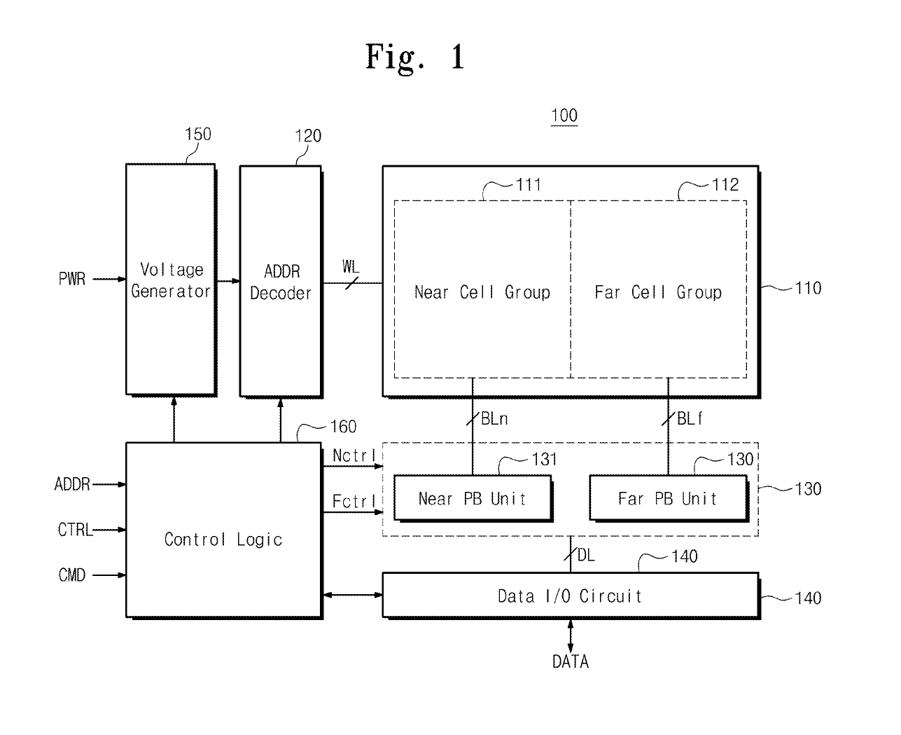

FIG. 1 is a block diagram illustrating a nonvolatile memory device according to an embodiment of the inventive concept. Referring to FIG. 1, a nonvolatile memory device 100 comprises a memory cell array 110, an address decoder 120, a page buffer circuit 130, a data input/output (I/O) circuit 140, a voltage generator 150, and control logic 160.

The nonvolatile memory device 100 may be configured to divide various groupings of memory cells (hereafter, a “memory cell grouping” or a “memory cell group”) in accordance with one or more distance(s) (or in accordance with one or more range(s) of distance) between each memory cell grouping and a program voltage source. In view of such distance-based designations of memory cell groupings, the nonvolatile memory device 100 may independently control the execution of a program operation by memory cell grouping. For example, the nonvolatile memory device 100 may respectively and independently define a threshold voltage level indicating a corresponding “program state” for each one of a plurality of memory cell groupings. Using this approach, the nonvolatile memory device 100 may improve the overall speed and efficiency of the program operation.

In certain embodiments of the inventive concept, the memory cell array 110 may include a plurality of cell strings. As has been noted, the memory cell array 110 may be divided into a plurality of memory blocks. The memory cell array 110 may be connected with the address decoder 120 via a plurality of word lines WL. The memory cell array 110 may be connected with the page buffer circuit 130 via a plurality of bit lines BLn and BLf.

More particularly, in the embodiment illustrated in FIG. 1, the memory cell array 110 includes a “first memory cell grouping” referred to as a near memory cell group 111, as well as a “second memory cell grouping” referred to as a far memory cell group 112. The near memory cell group 111 and far memory cell group 112 may share one or more word line(s). The near memory cell group 111 and far memory cell group 112 will include a plurality of memory strings.

In the illustrated example of FIG. 1, the near memory cell group 111 and far memory cell group 112 are divided form one another according to a “reference distance” measured in the word line direction from the address decoder 120. The near memory cell group 111 include memory strings relatively “near” the address decoder 120 (that is, less than the reference distance from the address decoder 120), while the far memory cell group 112 includes memory strings relatively “far” from the address decoder 120 (that is, more than the reference distance from the address decoder). Thus, the terms “near” and “far” are relative terms that may be understood in the context of the reference distance.

Of note, the respective memory cells in the near memory cell group 111 and the far memory cell group 112 will be programmed—using a common program operation—in relation to different target threshold voltages for a same “program state” (e.g., one program state selected from the program data states ‘1’ and ‘0’ for a 1-bit memory cell, or one program state selected from the program states ‘00’, ‘10’, “01”, and ‘11 for a 2-bit memory cell, etc.) under the control of the control logic 160.

The embodiments of FIG. 1 illustrates the memory cell array 110 being divided into only two (2) memory cell groupings, for ease of explanation. However, those skilled in the art will recognize that inventive concept is not limited to this particular configuration. The memory cell array 110 may be logically divided into three (3) or more memory cell groupings using two (2) or more reference distances. Of additional note, the reference distance noted in the description of FIG. 1 is defined in a word line direction from the address decoder 120. However, this is just one example of a reference distance definition. Others may be used to good advantage in other embodiments of the inventive concept.

As is conventionally understood, the address decoder 120 may select one of the memory blocks in the memory cell array 110 under the control of the control logic 160, and select one or more word line(s) in the selected memory block. The address decoder 120 may then apply a control voltage to the selected word line(s) of the selected memory block.

For example, during a program operation, the address decoder 120 may provide in sequence a program voltage and a verification voltage to a selected word line, and also provide a pass voltage to unselected word lines. During a read operation, the address decoder 120 may provide a selection read voltage to a selected word line and a non-selection read voltage to an unselected word line.

The page buffer circuit 130 may operate as a write driver or a sense amplifier according to a mode of operation. During a program operation, the page buffer circuit 130 may provide a bit line of the memory cell array 110 with a bit line voltage corresponding to the “program data” to be programmed. During a read operation, the page buffer circuit 130 may sense and latch “read data” stored at a selected memory cell via a bit line, and may transfer the latched read data to the data I/O circuit 140.

In the illustrated embodiment of FIG. 1, the page buffer circuit 130 includes a near page buffer unit 131 and a far page buffer unit 132. The near page buffer unit 131 is connected to a first set of bit lines BLn connected with the memory cells designated in the near memory cell group 111, and the far page buffer unit 132 is connected to a second set of bit lines BLf connected to the memory cells designated in the far memory cell group 112.

The near page buffer unit 131 may be used to process program/read data (DATA) being programmed to/read from the near memory cell group 111 in response to a near control signal Nctrl received from the control logic 160, and the far page buffer unit 132 may be sued to process program/read data being programmed to/read from the far memory cell group 112 in response to a far control signal Fctrl received from the control logic 160.

In certain embodiments, the near page buffer unit 131 and far page buffer unit 132 may respectively include a plurality of page buffers, each respectively corresponding to one of the plurality of bit lines. Each page buffer may be configured to adjust a precharge voltage level or a “develop time” for the precharge voltage on a corresponding bit line in response to control signals received from the control logic 160.

The data I/O circuit 140 may be used to provide the page buffer circuit 130 with program data during a program operation, and to output read data from the page buffer circuit 130 to an external device during a read operation. The data I/O circuit 140 also be used to transfer input addresses and/or commands to the control logic 160. The address decoder 120, page buffer circuit 130, and voltage generator 150 may be understood as a data I/O unit that provides program data to the memory cell array 110 during a program operation.

Here, the voltage generator 150 may receive a power signal PWR from an external device to generate the word line voltages required to program or write data. The word line voltages are usually applied to the memory cell array 110 through the address decoder 120.

The control logic 160 may be sued to control the program, read, and erase operations executed by the nonvolatile memory device 100 in response to various externally applied address ADDR, control CTRL, and/or command CMD signal(s). Thus, the control logic 160 may be used to control the address decoder 120, page buffer circuit 130, data I/O circuit 140, and voltage generator 150.

During data processing operation (e.g., a program operation or a read operation), the control logic 160 may independently control the operation of the near and far page buffer units 131 and 132 using the near and far control signals Nctrl and Fctrl. Under the control of the control logic 160, the near memory cell group 111 and far memory cell group 112 may be programmed to have different threshold voltage levels with respect to the same program state. As a result different, respective threshold voltage distributions will emerge for memory cells of the near memory cell group 111 programmed to a program state, as compared with memory cells of the far memory cell group 112 programmed to the same program state. These different threshold voltage distributions will have different lower limit values with respect to the same program state.

During a program operation, the address decoder 120 will apply a program voltage to a selected word line. The speed (hereinafter, “program speed”) with which the program voltage may be communicated to a selected memory cell along the selected word line will vary according to the distance separating the address decoder 120 (i.e., the program voltage source) from the selected memory cell. Indeed, program speed for a selected memory cell is inversely proportional to the distance separating the program voltage source from the selected memory cell. Hence, the program speeds for the memory cells designated in the near memory cell group 111 will be faster than the program speeds for the memory cells designated in the far memory cell group 112.

If the time allotted for execution of a program operation is relatively short, the memory cells in the far memory cell group 112 may not be sufficiently supplied with the program voltage, relative to the memory cells of the near cell group 111, due to differences in program speed. Thus, using conventional programming techniques, one or more additional programming iterations (or program loop(s)) may be required for some or all of the memory cells in the far memory cell group 112 to reach the same target program voltage as the memory cells in the near memory cell group 111. This outcome slows the overall speed and efficiency of the memory system.

However, certain embodiments of the inventive concept recognize that where the same program voltage is applied to a selected word line, a lower limit value for a threshold voltage distribution associated with the program voltage for the far memory cell group 112 should be lower than the lower limit value for the threshold voltage distribution associated with the program voltage for the near memory cell group 111. This approach avoids the additional programming iterations that may be conventionally necessary.

That is, to compensate for program speed differences between the memory cell groups 111 and 112, the nonvolatile memory device 100 of FIG. 1 may apply different program verification operations with respect to the same program state for each one of the near and far memory cell groups 111 and 112. Using better defined and different program verification operation, the near and far memory cell groups 111 and 112 may be successfully programmed in relation to different lower limit values for different threshold voltage distributions with respect to the same program state. In a similar approach, the nonvolatile memory device 100 may apply different read voltages to the near and far memory cell groups 111 and 112 during a subsequent read operation.

In certain embodiments of the inventive concept like the one shone in FIG. 1, during a program verification operation executed by the nonvolatile memory device 100, a precharge voltage is applied to the memory cells of the far memory cell group 112 may be lower than a precharge voltage applied to the memory cells of the near memory cell group 111, because in the nonvolatile memory device 100, memory cells farther away from the address decoder 120 will be programmed to a lower target program voltage by reducing the precharge voltage level.

In this regard, the nonvolatile memory device 100 may provide different read operations with respect to the near and far memory cell groups 111 and 112 according to a threshold voltage level. In the nonvolatile memory device 100, during a read operation, memory cells having different threshold voltages may be discriminated to have the same program state by reducing the precharge voltage level applied to the memory cells farther away from the address decoder 120.

In other embodiments of the inventive concept, during a program verification operation executed by the nonvolatile memory device 100, a develop time for the near memory cell group 111 may be different from a develop time for the far memory cell group 112. That is, a first develop time for the far memory cell group 112 may be less than a second develop time for the near memory cell group 111. Memory cells farther away from the address decoder 120 may be programmed to a lower target program voltage by reducing the develop time.

In this regard, the nonvolatile memory device 100 may provide different read operations with respect to the near and far memory cell groups 111 and 112 according to a threshold voltage level. During a read operation, memory cells having different threshold voltages may be discriminated to have the same program state by reducing the develop time for memory cells farther away from the address decoder 120.

In the nonvolatile memory device 100, since there is no need to apply a program voltage to the memory cells designated in the far memory cell group 112 for a relatively long time, overall program operation execution time may be reduced. Also, since a given target program voltage level for the memory cell designated in the far memory cell group 112 is lower than that of the near memory cell group 111, additional programming iterations conventionally required to increase threshold voltages of the memory cell in the far memory cell group 112 may not be required. As the number of program iteration (or loops) is reduced, the nonvolatile memory device 100 may have a reduced overall programming time with fewer program disturbance possibilities.

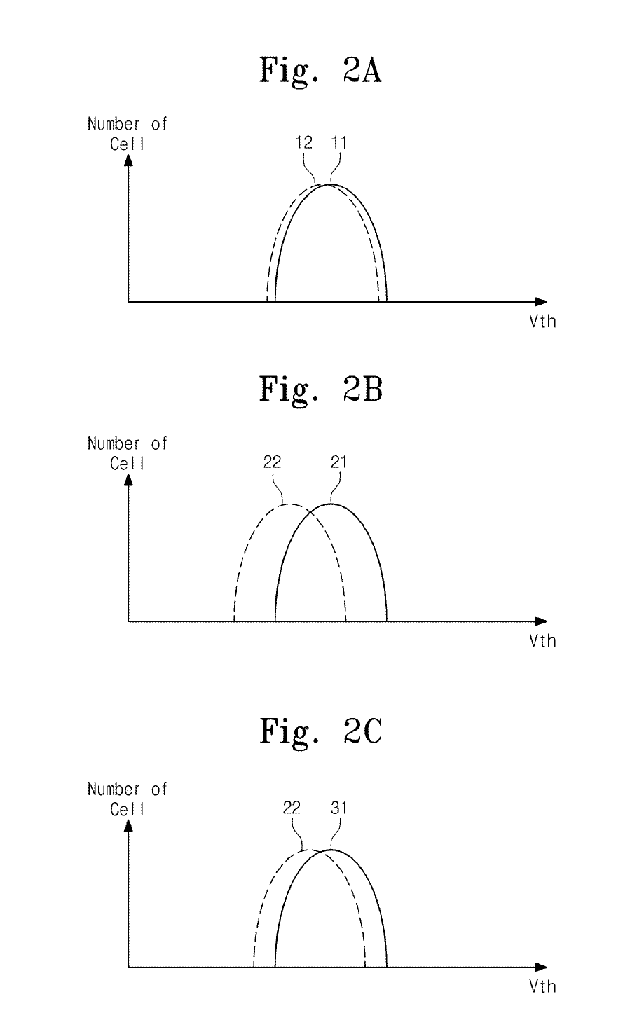

FIGS. 2A, 2B and 2C are diagrams illustrating threshold voltages when relatively near and far memory cells in the nonvolatile memory device of FIG. 1 are programmed. In FIGS. 2A, 2B and 2C, the horizontal axis indicates a threshold voltage level, and the vertical axis indicate a number of programmed cells filling within the respective threshold voltage distributions.

FIG. 2A is a diagram illustrating threshold voltage distributions for near and far memory cells when a program voltage is applied during a relatively long program execution period, sufficient to program the far memory cells. Thus, if the program execution time is sufficiently long to allow successful programming of even the farthest memory cells, a single (or very limited narrow set of) program verification voltage(s) may be used to accurately discriminate the program state of memory cells regardless of their relative program speed differences because the threshold voltage distribution 11 for near cells is almost identical to that of the threshold voltage distribution 12 of far cells.

Yet, relatively long program execution times will increase the overall time required to perform a program operation, and relatively long program execution times increase the potential for program disturbance.

FIG. 2B is a diagram illustrating threshold voltage distributions for near and far cells when a program voltage is applied during a relatively short program execution time.

Since a program execution time is relatively short, the overall time required to execute a program operation may be reduced, and the potential for program disturbance may be reduced. Yet, as the program execution time is reduced, a single (or very limited narrow set of) program verification voltage(s) may prove inadequate to accurately discriminate both near cell and far cells due to inherent program speed differences. Note that the lower limit value of threshold voltage distribution 22 associated with the far cells is much lower than the lower limit value of threshold voltage distribution 21 associated with the of near cells.

Hence, the number of program loops may increase to form the threshold voltage distribution 22 for near cells like the threshold voltage distribution 12 of FIG. 2A. An increase in the number of program loops will cause an overall increase in a time required to execute the program operation. Also, as the number of program loops increases, a higher program voltage may be applied to the far cells. Thus, program disturbance may increase.

FIG. 2C shows threshold voltage distributions when programming of the near and far cells is complete (i.e., after additional program iterations). Referring to FIG. 2C, upon program completion, the lower limit values for the threshold voltage distributions 22, 31 for the near and far cells yet may be different with respect to the same program state.

In contrast, a nonvolatile memory device according to embodiments of the inventive concept will be configured to program near cells and far cells according to different threshold voltage levels with respect to the same program state. In this manner, such nonvolatile memory devices may prevent a given program verification voltage from being inadequate to discriminate both near cells and far cells.

With the above description, a program execution time of a program operation may be shortened. Also, since a target program voltage level of a far cell is lower than that of a far cell, additional program loops for increasing threshold voltages of far cells may not be required. As the number of program loops decreases, the nonvolatile memory device may have reduced program time and program disturbance.

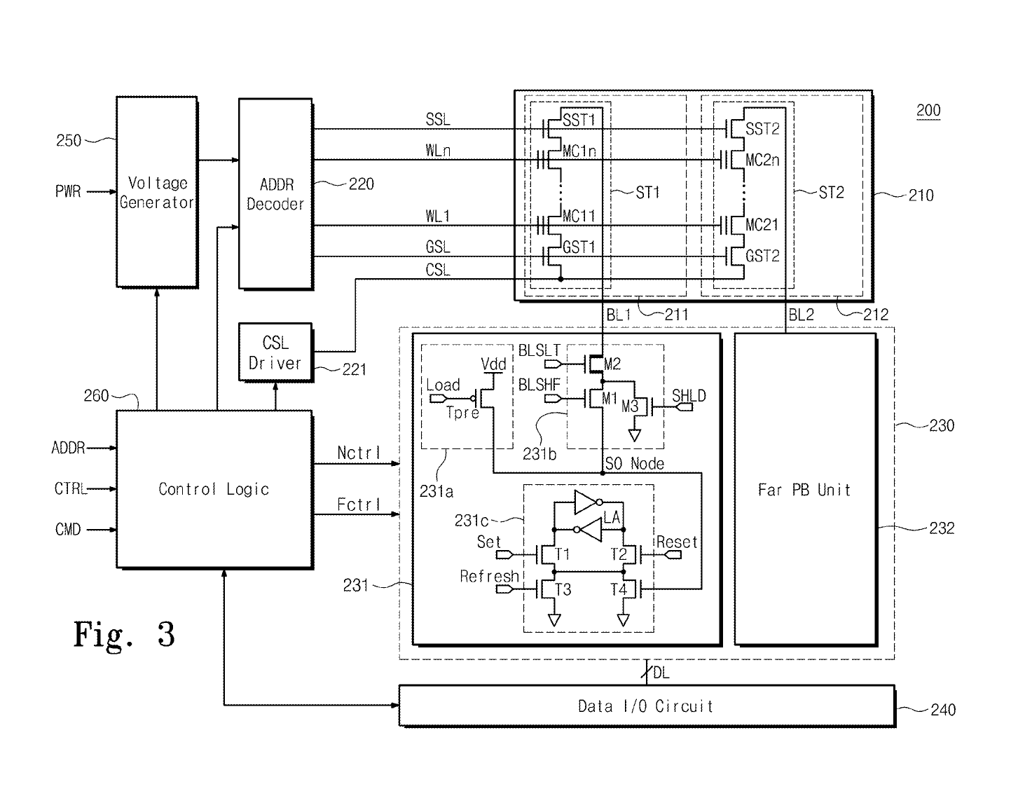

FIG. 3 is a block diagram illustrating a nonvolatile memory device according to an embodiment of the inventive concept. Referring to FIG. 3, a nonvolatile memory device 200 comprises a memory cell array 210, an address decoder 220, a common source line driver 221, a page buffer circuit 230, a data I/O circuit 240, a voltage generator 250, and control logic 260.

The common source line driver 221 may be connected with the memory cell array 210 via a common source line CSL. The common source line driver 221 may apply a common source line voltage to the common source line CSL.

The nonvolatile memory device 200 of FIG. 3 may have substantially the same structure as the nonvolatile memory device 100 of FIG. 1, except for the CSL driver 221, the page buffer circuit 230, and the control logic 260. Thus, duplicated component descriptions will be omitted.

The memory cell array 210 may include a near cell group 211 and a far cell group 212. The near and far cell groups 211 and 212 may include a plurality of memory strings. In FIG. 3, there is illustrated an example where each of the near and far cell groups 211 and 212 includes one memory string. The memory string ST1 may include a string selection transistor SST1, a plurality of memory cells MC11 to MC1n, and a gate selection transistor GST1, and the memory string ST2 may include a string selection transistor SST2, a plurality of memory cells MC21 to MC2n, and a gate selection transistor GST2.

The nonvolatile memory device 200 may improve program operation efficiency by compensating for a program speed difference between the memory strings ST1 and ST2 having different distances from the address decoder 220. For example, during a program verification operation, the nonvolatile memory device 200 may provide different precharge voltage levels to bit lines connected with the near and far cell groups 211 and 212. In other embodiments, during a program verification operation, the nonvolatile memory device 200 may operate such that develop times of the near and far cell groups 211 and 212 are different from each other.

The page buffer circuit 230 may include a near page buffer unit 231 and a far page buffer unit 232. Each of the near and far page buffer units 231 and 232 may include a plurality of page buffers respectively connected with bit lines. In FIG. 3, only one page buffer is illustrated in detail. A page buffer may include a precharge circuit 231a, a switch circuit 231b, and a sense and latch circuit 231c.

The precharge circuit 231a, the switch circuit 231b, and the sense and latch circuit 231c of the page buffer may operate responsive to control signals Nctrl and Fctrl of the control logic 260. Page buffers in the near page buffer unit 231 may operate responsive to the control signal Nctrl, and page buffers in the far page buffer unit 232 may operate responsive to the control signal Fctrl. The control signals Nctrl and Fctrl may include a load signal Load, a bit line voltage control signal BLSHF, a bit line selection signal BLSLT, a shield signal SHLD, and so on.

The precharge circuit 321a may supply a precharge voltage to a sense node SO Node. The precharge circuit 321a may include a transistor Tpre which is turned on or off according to the load signal Load.

The switch circuit 231b may include transistors M1, M2, and M3. The transistor M1 may precharge a bit line to a predetermined voltage level in response to the bit line voltage control signal BLSHF. The transistor M2 may select a bit line in response to the bit line selection signal BLSLT. The transistor M3 may discharge a page buffer in response to the shield signal SHLD.

The sense and latch circuit 231c may detect a voltage level of the sense node SO Node. Data may be latched according to the detected voltage level of the sense node SO Node. The sense and latch circuit 231c may include a latch LA and transistors T1 to T4. The sense and latch circuit 231c may operate responsive to control signals Set, Refresh, and Reset of the control logic 260.

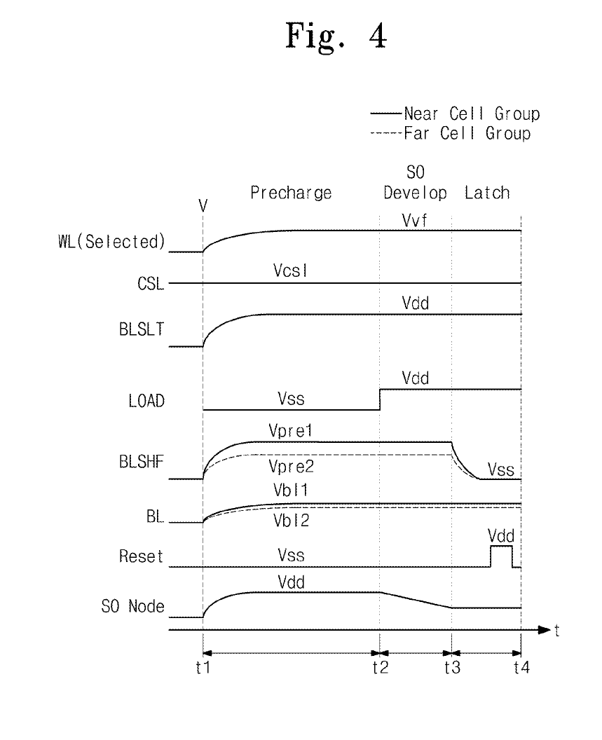

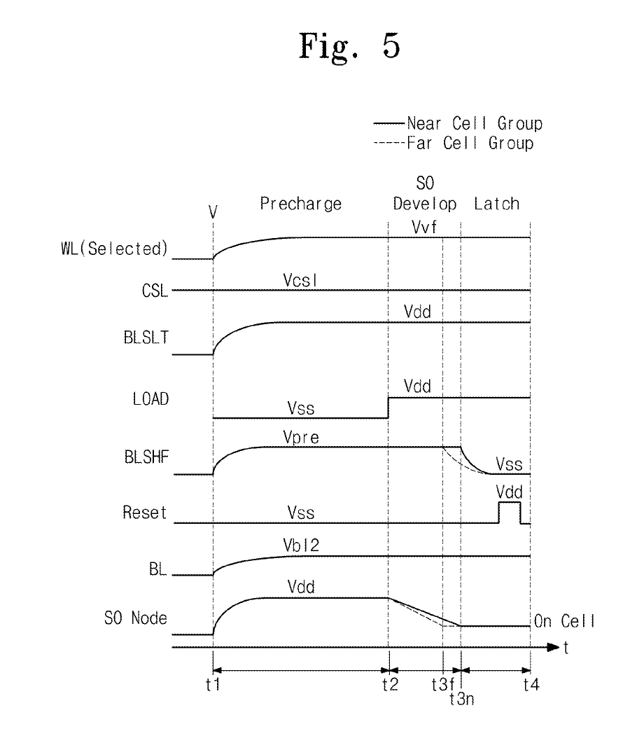

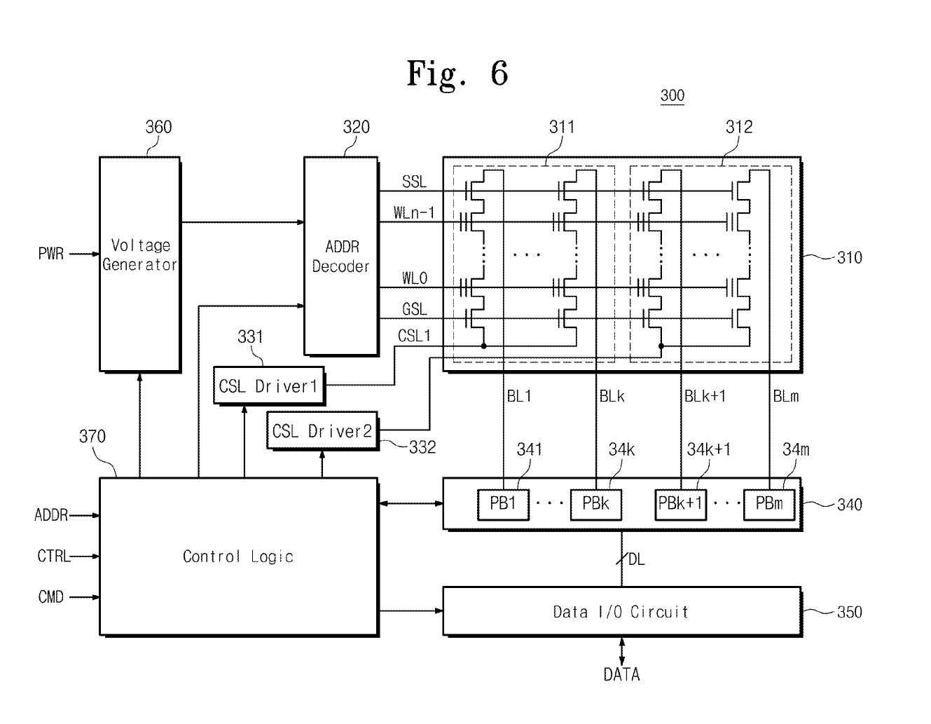

Hereafter, a program verification method that may be executed using the page buffer circuit 230 according to an embodiment of the inventive concept will be described with reference to FIGS. 4 and 5.

FIG. 4 is a timing diagram further illustrating a program verification method that may be used by a nonvolatile memory device according to an embodiment of the inventive concept. Signals, not illustrated in FIG. 4, from among the signals variously described in relation to FIG. 3 may transition to a ground level during the program verification operation. Using the program verification method of FIG. 4, different levels of precharge voltages may be applied to bit lines connected as between the near and far memory cell groups 211 and 212.

During the program verification operation, a verification voltage Vvf may be applied to a selected word line, and a common source line voltage Vcs1 may be applied to a common source line CSL.

During the program verification operation, a transistor M2 connected with a selected bit line may be turned on. A bit line selection signal BLSLT may have a power supply voltage level to turn on the transistor M2.

During a precharge period t1 to t2, a precharge circuit 231a may be turned on to precharge a sensing node SO Node. For this, a precharge control signal LOAD may transition to a ground voltage level. The sensing node SO Node may be precharged with a power supply voltage Vdd in response to the precharge control signal LOAD.

A bit line voltage control signal BLSHF may be set to a predetermined voltage level to precharge a bit line connected with the sensing node SO Node. The bit line may be precharged with a predetermined bit line voltage in response to the bit line voltage control signal BLSHF. Precharging of the bit line may be performed until the precharge circuit 231a is turned off.

During a develop period t2 to t3, the precharge circuit 231a may be turned off. The precharge circuit 231a may be turned off by the precharge control signal LOAD having a power supply voltage level.

Since the precharge circuit 231a is turned off and transistors M1 and M2 of a switch circuit 231b remain in a turn-on state, a voltage of the sensing node SO Node may decrease according to a program state of a selected memory cell. For example, a voltage of the sensing node SO Node may rapidly decrease toward a bit line voltage level when the selected memory cell is an on-cell. A voltage of the sensing node SO Node may slowly decrease by off-cell leakage when the selected memory cell is an on-cell.

During a latch period t3 to t4, a voltage level of the sensing node SO Node may be detected by a sense and latch circuit 231c, and a reset signal Reset may be activated. Data may be latched according to the detected voltage level of the sensing node SO Node.

With the program verification method of the inventive concept, bit lines connected with near and far memory cell groups 211 and 212 may be precharged with different levels of precharge voltages under the control of control logic 260.

During the precharge period t1 to t2, the bit line voltage control signal BLSHF corresponding to the near cell group 211 may have a near precharge voltage Vpre1, and the bit line voltage control signal BLSHF corresponding to the far cell group 212 may have a far precharge voltage Vpre2.

A bit line corresponding to the near cell group 211 may be precharged with a near bit line voltage Vbl1 in response to the bit line voltage control signal BLSHF. A bit line corresponding to the far cell group 212 may be precharged with a far bit line voltage Vbl2. Herein, the near bit line voltage Vbl1 may be higher than the far bit line voltage Vbl2.

As a bit line precharge voltage decreases, the amount of current flowing via a memory cell may decrease. In this case, a voltage of the sensing node SO Node may decrease more slowly. Since the far bit line voltage Vbl2 is lower than the near bit line voltage Vbl1, a decrease in a cell current may make a threshold voltage of the far cell group 212 be measured to be higher than an actual threshold voltage. Thus, although the same verification voltage is used, the far cell group 212 may be programmed to have a lower limit value of a threshold voltage distribution lower than that of the near cell group 211.

A program operation according to an embodiment of the inventive concept may be performed during a relatively short program execution time. Also, since a target program voltage level for a far cell is lower than that of a near cell, additional program loops conventionally required to increase the threshold voltage of a far cell are not required. As the number of program loops decreases, a nonvolatile memory device will have reduced overall program time and reduced possibility of program disturbance.

FIG. 5 is a timing diagram illustrating a program verification method for a nonvolatile memory device according to another embodiment of the inventive concept. Signals, not illustrated in FIG. 5, from among the signals described in relation to FIG. 3 may transition to a ground level during the program verification operation. Using the program verification method of FIG. 5, the nonvolatile memory device 200 may independently control respective develop times for bit lines connected as between the near and far memory cell groups 211 and 212.

During the program verification operation, a verification voltage Vvf may be applied to a selected word line, and a common source line voltage Vcs1 may be applied to a common source line CSL.

During the program verification operation, a transistor M2 connected with a selected bit line may be turned on. A bit line selection signal BLSLT may have a power supply voltage level to turn on the transistor M2.

During a precharge period t1 to t2, a precharge circuit 231a may be turned on to precharge a sensing node SO Node. For this, a precharge control signal LOAD may transition to a ground voltage level. The sensing node SO Node may be precharged with a power supply voltage Vdd in response to the precharge control signal LOAD.

A bit line voltage control signal BLSHF may be set to a bit line precharge voltage level Vpre to precharge a bit line connected with the sensing node SO Node. The bit line may be precharged with a bit line voltage Vbl in response to the bit line voltage control signal BLSHF. Precharging of the bit line may be performed until the precharge circuit 231a is turned off.

During a develop period t2 to t3, the precharge circuit 231a may be turned off. The precharge circuit 231a may be turned off by the precharge control signal LOAD having a power supply voltage level.

Since the precharge circuit 231a is turned off and transistors M1 and M2 of a switch circuit 231b remain at a turn-on state, a voltage of the sensing node SO Node may decrease according to a program state of a selected memory cell. For example, a voltage of the sensing node SO Node may rapidly decrease toward a bit line voltage level when the selected memory cell is an on-cell. A voltage of the sensing node SO Node may slowly decrease by off-cell leakage when the selected memory cell is an on-cell.

During a latch period, a voltage level of the sensing node SO Node may be detected by a sense and latch circuit 231c, and a reset signal Reset may be activated. Data may be latched according to the detected voltage level of the sensing node SO Node.

With the program verification method of the inventive concept, develop times of bit lines connected with near and far memory cell groups 211 and 212 may be different.

Bit lines connected with the near cell group 211 may be sensed during a near develop time t2 to t3n. Bit lines connected with the far cell group 212 may be sensed during a far develop time t2 to t3f. Herein, the far develop time t2 to t3f may be shorter than the near develop time t2 to t3n.

As a develop time decreases, the amount of current flowing to a bit line from the sensing node SO Node may decrease. In this case, a voltage of the sensing node SO Node may decrease more slowly. Since the far develop time t2 to t3f is shorter than the near develop time t2 to t3n, a decrease in a cell current may make a threshold voltage of the far cell group 212 be measured to be higher than an actual threshold voltage. Thus, although the same verification voltage is used, the far cell group 212 may be programmed to have a lower limit value of a threshold voltage distribution lower than that of the near cell group 211.

A program operation according to an embodiment of the inventive concept may be performed during a short program execution time. Also, since a target program voltage level of a far cell is lower than that of a near cell, additional program loops for increasing a threshold voltage of a far cell may not be required. As the number of program loops decreases, a nonvolatile memory device may have reduced program time and program disturbance.

FIG. 6 is a block diagram illustrating a nonvolatile memory device according to another embodiment of the inventive concept. Referring to FIG. 6, a nonvolatile memory device 300 may include a memory cell array 310, an address decoder 320, first and second common source line drivers 331 and 332, a page buffer circuit 340, a data I/O circuit 350, a voltage generator 360, and control logic 370. The memory cell array 310 may include a near cell group 311 and a far cell group 312.

In FIG. 6, the data I/O circuit 350 and the voltage generator 360 may be the same as a data I/O circuit 140 and a voltage generator 150 in FIG. 1. Thus, a duplicated description is omitted.

At a program verification operation, the nonvolatile memory device 300 may provide different levels of common source line voltages to the near and far memory cell groups 311 and 312. With this program verification operation, there may be corrected a program speed difference between memory cells which is generated since distances between the memory cells and the address decoder 320 are different. Thus, it is possible to improve program efficiency.

The memory cell array 310 may be connected with the address decoder 320 via word lines or selection lines. The memory cell array 310 may be connected with the page buffer circuit 340 via bit lines.

The memory cell array 310 may include a near cell group 311 and a far cell group 312. The near cell group 311 and the far cell group 312 may share the same word line. The near cell group 311 and the far cell group 312 may include a plurality of memory strings.

The near cell group 311 may be connected with the first common source line driver 331 via a first common source line CSL1, and the far cell group 312 may be connected with the second common source line driver 332 via a second common source line CSL2.

The address decoder 320 may select one of memory blocks in the memory cell array 310 in response to the control of the control logic 370. The address decoder 320 may select one of word lines in the selected memory block. The address decoder 320 may transfer a voltage to a word line of the selected memory block.

The page buffer circuit 340 may operate as a write driver or a sense amplifier according to a mode of operation. At a program operation, the page buffer circuit 340 may provide a bit line of the memory cell array 310 with a bit line voltage corresponding to data to be programmed. At a read operation, the page buffer circuit 340 may sense and latch data stored at a selected memory cell via a bit line, and may transfer the latched data to the data I/O circuit 350.

The page buffer circuit 340 may include a plurality of page buffers PB1 to PBm corresponding to the bit lines, respectively. The page buffers PB1 to PBm may be the same or substantially the same as that in FIG. 3, and a duplicated description thereof is thus omitted.

The control logic 370 may control program, read, and erase operations of the nonvolatile memory device 300 in response to an address ADDR, a control signal CTRL, and a command CMD from an external device. The control logic 370 may control the address decoder 320, the page buffer circuit 340, the data I/O circuit 350, and the voltage generator 360.

At a data processing operation, the control logic 370 may control the first and second common source line drivers 331 and 332 such that common source line voltages applied to the near and far memory cell groups 311 and 312 are controlled independently. Under the control of the control logic 370, the near cell group 311 and the far cell group 312 may be programmed to have different lower limit values with respect to the same program state.

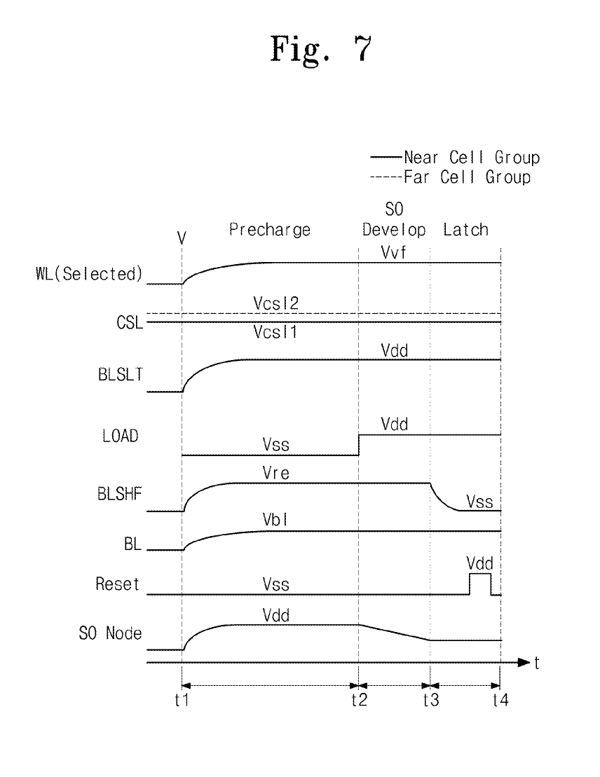

FIG. 7 is a timing diagram illustrating a program verification method of a nonvolatile memory device of FIG. 6. With a program verification method of FIG. 7, a nonvolatile memory device 300 may provide different levels of common source line voltages to common source lines connected with near and far memory cell groups 311 and 312.

At a program verification operation, a verification voltage Vvf may be applied to a selected word line. A word line voltage during the program verification operation of the nonvolatile memory device 300 is well known in the art, and a description thereof is thus omitted.

During the program verification operation, a transistor M2 connected with a selected bit line may be turned on. A bit line selection signal BLSLT may be set to have a power supply voltage level to turn on the transistor M2.

A first common source line voltage Vcsl1 may be applied to a common source line CSL1 connected with the near cell group 311, and a second common source line voltage Vcsl2 may be applied to a common source line CSL2 connected with the far cell group 313.

During a precharge period t1 to t2, a precharge circuit may be turned on to precharge a sensing node SO Node. For this, a precharge control signal LOAD may transition to a ground voltage level. The sensing node SO Node may be precharged with a power supply voltage Vdd in response to the precharge control signal LOAD.

A bit line voltage control signal BLSHF may be set to a precharge voltage Vpre to precharge a bit line connected with the sensing node SO Node. The bit line may be precharged with a bit line voltage Vbl in response to the bit line voltage control signal BLSHF. Precharging of the bit line may be performed until the precharge circuit is turned off.

During a develop period t2 to t3, the precharge circuit may be turned off. The precharge circuit may be turned off by the precharge control signal LOAD having a power supply voltage level.

Since the precharge circuit is turned off and transistors M1 and M2 of a switch circuit remain at a turn-on state, a voltage of the sensing node SO Node may decrease according to a program state of a selected memory cell. For example, a voltage of the sensing node SO Node may rapidly decrease toward a bit line voltage level when the selected memory cell is an on-cell. A voltage of the sensing node SO Node may slowly decrease by off-cell leakage when the selected memory cell is an on-cell.

During a latch period t3 to t4, a voltage level of the sensing node SO Node may be detected by a sense and latch circuit, and a reset signal Reset may be activated. Data may be latched according to the detected voltage level of the sensing node SO Node.

With the program verification method of the inventive concept, common source lines connected with the near and far memory cell groups 311 and 312 may be set to different levels under the control of the control logic 370.

During the program verification operation, a first common source line voltage Vcsl1 may be applied to the common source line CSL1 connected with the near cell group 311. A second common source line voltage Vcsl2 may be applied to the common source line CSL2 connected with the far cell group 312. The second common source line voltage Vcsl2 may be higher than the first common source line voltage Vcsl1.

As a common source line voltage increases, the amount of current flowing via a memory cell may decrease. In this case, a voltage of the sensing node SO Node may decrease more slowly. Since the second common source line voltage Vcsl2 is higher than the first common source line voltage Vcsl1, a decrease in a cell current may make a threshold voltage of the far cell group 312 be measured to be higher than an actual threshold voltage. Thus, although the same verification voltage is used, the far cell group 312 may be programmed to have a lower limit value of a threshold voltage distribution lower than that of the near cell group 311.

A program operation according to an embodiment of the inventive concept may be performed over a markedly reduced program execution time. Also, since a target program voltage level for a far cell is lower than that of a near cell, additional program loops conventionally required to increase the threshold voltage of a far cell are not required. As the number of program loops decreases, a nonvolatile memory device will have a reduced overall program time with a reduced possibility of program disturbance.

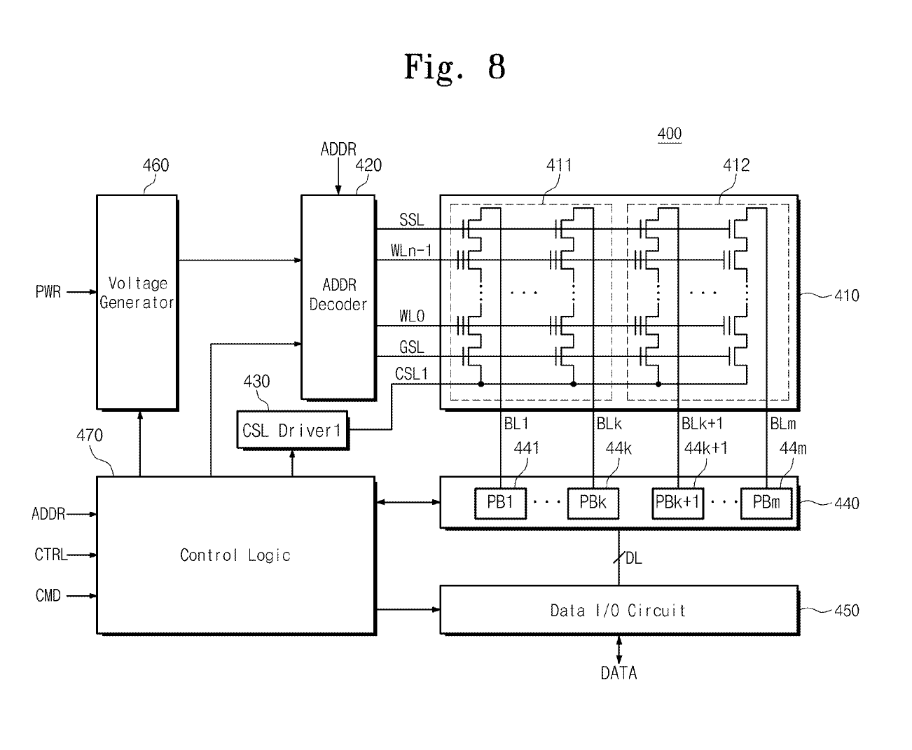

FIG. 8 is a block diagram illustrating a nonvolatile memory device according to still another embodiment of the inventive concept. Referring to FIG. 8, a nonvolatile memory device 400 comprises a memory cell array 410, an address decoder 420, a common source line driver 430, a page buffer circuit 440, a data I/O circuit 450, a voltage generator 460, and control logic 470. The memory cell array 410 includes a near cell group 411 and a far cell group 412.

In FIG. 8, the address decoder 420, the page buffer circuit 440, the data I/O circuit 450, and the voltage generator 460 may have substantially the same respective structures and operations as the address decoder 320, page buffer circuit 340, data I/O circuit 350, and voltage generator 360 of FIG. 6. Thus, duplicated descriptions will be omitted.

During a program verification operation, the nonvolatile memory device 400 may provide different levels of verification voltages to the near and far memory cell groups 411 and 412. Since the near and far memory cell groups 411 and 412 share the same word line, a verification voltage may be provided plural times to provide different levels of verification voltages. With this verification operation, the nonvolatile memory device 400 may improve program efficiency by correcting a program speed difference between memory cells which is generated since distances between the memory cells and the address decoder 420 are different.

The memory cell array 410 may be connected with the address decoder 420 via word lines WL0 to WLn−1 or selection lines SSL and GSL. The memory cell array 410 may be connected with the common source line driver 430 via a common source line CSL. The memory cell array 410 may be connected with the page buffer circuit 440 via bit lines BL0 to BLm.

The memory cell array 410 may include a near cell group 411 and a far cell group 412. The near cell group 411 and the far cell group 412 may share the same word line.

The address decoder 420 may select one of memory blocks in the memory cell array 410 in response to the control of the control logic 370. The address decoder 420 may select one of word lines in the selected memory block. The address decoder 420 may transfer a voltage to a word line of the selected memory block.

The common source line driver 430 may provide a common source line voltage to the common source line CSL of the memory cell array 410 in response to the control of the control logic 470.

The control logic 470 may control program, read, and erase operations of the nonvolatile memory device 400 in response to an address ADDR, a control signal CTRL, and a command CMD from an external device. The control logic 370 may control the address decoder 420, the common source line driver 430, the page buffer circuit 440, the data I/O circuit 450, and the voltage generator 460.

During a data processing operation (e.g., a program operation), the control logic 470 may apply different levels of verification voltages to the near and far memory cell groups 411 and 412. A verification voltage for the near cell group 412 may be lower than that of the far cell group 412. Thus, the far cell group 412 may be programmed to have a relatively low threshold voltage with respect to the same program state.

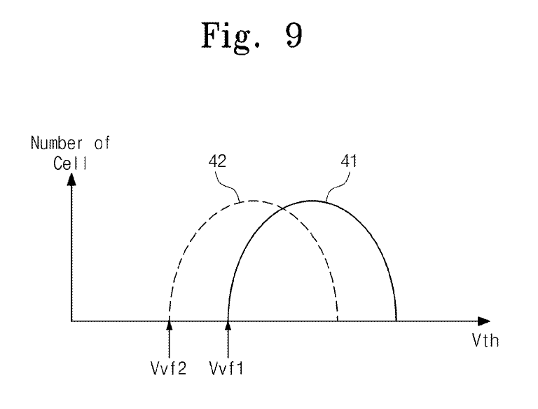

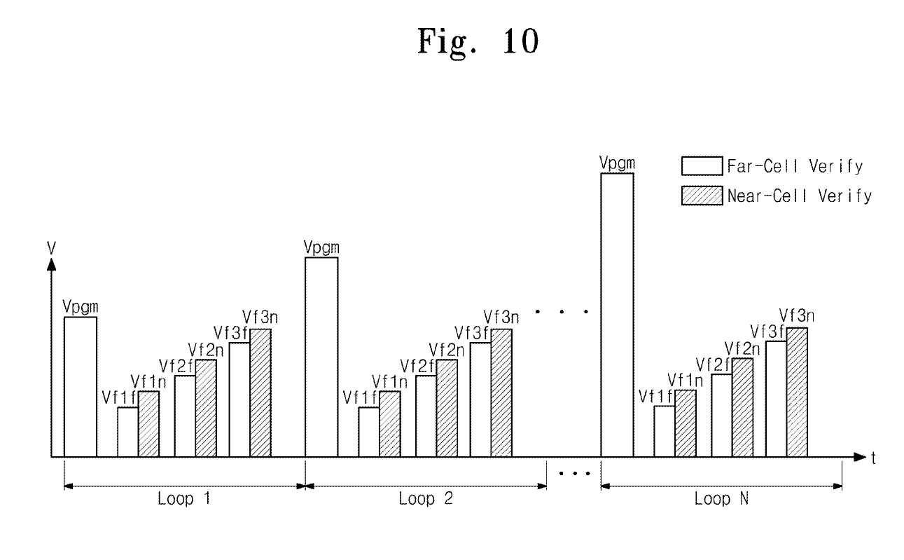

The nonvolatile memory device 400 may correct a program speed difference between the near cell group 411 and the far cell group 412 by providing different levels of verification voltages to the near cell group 411 and the far cell group 412. This possibility will be more fully described with reference to FIGS. 9 and 10.

FIG. 9 is a diagram illustrating threshold voltage distributions for near and far memory cell groups with respect to the same program state. In FIG. 9, the horizontal axis again indicates a threshold voltage level, and the vertical axis indicate a number of cells programmed to the program state.

Referring to FIG. 9, a lower limit value of a threshold voltage distribution 42 for the far memory cell grouping is lower than a lower limit value of a threshold voltage distribution 41 for the near memory cell grouping. To form the threshold voltage distributions illustrated in FIG. 9, during a program verification operation, a near memory cell grouping verification voltage Vvf1 is applied to respective memory cells in the near memory cell grouping, while a far memory cell grouping verification voltage Vvf2 lower than the near memory cell grouping verification voltage Vvf1 is applied to respective memory cells in the far memory cell grouping.

FIG. 10 is a diagram illustrating a set of word line voltages that may be applied during a program operation executed by the nonvolatile memory device of FIG. 8. In FIG. 10, the horizontal axis indicates time, and the vertical axis indicates word line voltage level. The nonvolatile memory device 400 of FIG. 8 is assumed to store data using multi-bit memory cells capable of storing data according to one of an erase state E0, a first program state P1, a second program state P2, and a third program state P3.

Referring to FIG. 10, a program voltage Vpgm for programming selected memory cells to target program states will be applied to a selected word line according to the data to be stored by the data I/O circuit 450. Afterwards, a sequence of program verification voltages may be sequentially provided to the selected word line to perform a program verification operation. The program voltage Vpgm may increase by a predetermine value according to each iteration of the constituent program loop for the program operation.

In the illustrated embodiment of FIG. 10, a lower first program state verification voltage Vf1f and an upper first program state verification voltage Vf1n are applied during a program verification operation direct to memory cells having been programmed to the first program state P1. During each successive program loop performed (e.g., Loop 1, Loop2 . . . Loop N), a lower second program state verification voltage Vf2f and an upper second program verification voltage Vf2n are applied during a program verification operation directed to memory cells having been programmed to the second program state P2, and a lower third program state verification voltage Vf3f and an upper third program state verification voltage Vf3n are applied during a program verification operation directed to memory cell having been programmed to the third program state P3.

In this context, any one or more of the verification voltages routinely used during a program verification operation and extending form (e.g.,) the lower first program state verification voltage Vf1f to the lower third program state verification voltage Vf3f may be used to discriminate a designated far memory cell grouping from designated a near memory cell grouping.

And consistent the previously described embodiment, since the far memory cell grouping may be supplied with a lower verification voltage in comparison to that of the near memory cell grouping, it may be programmed to have a lower threshold voltage with respect to the same program state. The nonvolatile memory device 400 may thus compensate for a program speed difference between the near and far memory cell groupings by providing different levels of verification voltages.

A program operation according to an embodiment of the inventive concept may be performed during a relatively short program execution time. Also, since a target program voltage level of a far memory cell is lower than that of a near memory cell, additional program loops for increasing the threshold voltage of the far memory cell may not be required. As the number of program loops decreases, a nonvolatile memory device may have reduced program time and program disturbance.

In addition, during a read operation, the control logic 470 of the nonvolatile memory device 400 in FIG. 8 may be used to control the page buffer circuit 440 to verify memory cells using a coarse/fine sensing approach. This may be performed to compensate for sensing noise during the read operation. In the coarse/fine sensing approach, any one or more of the first through third verification voltages Vf1f to Vf3f may be used as coarse verification voltage(s) for memory cells in the near memory cell grouping.

Here, the coarse/fine sensing approach wherein selected memory cells are continuously sensed two (2) times using different verification voltages to reduce overall sensing noise. That is, a coarse sensing operation may first be performed in which selected memory cells are sensed using a level lower than a given target verification level. As a result, the will be certain selected off cells among the sensed memory cells according to the coarse sensing operation. Then, a fine sensing operation will be performed in which the selected off cells are again sensed using the target verification level. Data sensed and latched by the fine sensing operation is considered final data.

The nonvolatile memory device 400 of FIG. 8 may use a verification voltage applied to a far memory cell grouping as a coarse verification voltage on memory cells designated in the near memory cell grouping. Since an on-cell current is reduced during the fine sensing operation performed on respective memory cells in the near memory cell grouping, common source line (CSL) noise may be reduced.

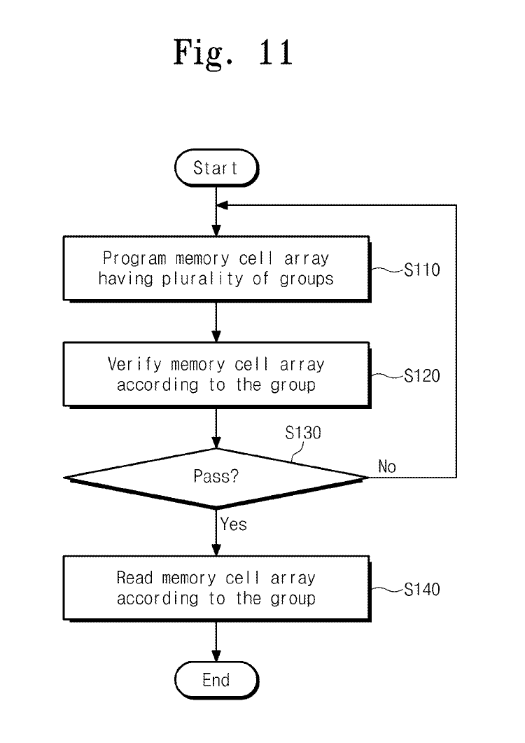

FIG. 11 is a flow chart summarizing a data processing method that may be executed by a nonvolatile memory device according to an embodiment of the inventive concept. Referring to FIG. 11, a data processing operation directed to the nonvolatile memory device may include a program operation and/or a read operation.

First, target memory cells are programmed in a memory cell array having been divided into a plurality of memory cell groups (S110). The memory cell array may be divided into the plurality of memory cell groups according to one or more reference distance(s) from a program voltage source. During the program operation, a program voltage will be applied to a selected word line, and the different memory cell groups will experience different programming times due to (e.g.,) the word line capacitance.

Next, a program verification operation for the target memory cells is performed (S120). If the program verification operation fails (S130=No), the target memory cells are again programed and verified (S110, S120) until such time as the program verification operation does not fail.

The program operation and the program verification operation may be performed according to memory cell groups designated within the memory cell array as described above. In particular, the program verification operation may be performed such that a far memory cell group has a target program voltage level lower than that of a near memory cell group. As a result, the near and far memory cell groups may be programmed to have different threshold voltage levels with respect to the same program state.

For example, the program verification operation may be performed such that different levels of program verification voltages are applied to the near and far memory cell groups. Since the near and far memory cell groups share the same word line, a program verification voltage may be applied to a word line plural times.

In other example embodiments, the program verification operation may be performed such that different levels of precharge voltages are applied to the near and far memory cell groups. A precharge voltage applied to the far memory cell group may be lower than a precharge voltage applied to the near memory cell group.

In still other example embodiments, the program verification operation may be performed such that different levels of common source line voltages are applied to the near and far memory cell groups. A common source line voltage applied to the far cell group may be higher than a common source line voltage applied to the near cell group.

In still other example embodiments, the program verification operation may be performed such that develop times of the near and far memory cell groups are different. A develop time of the far memory cell group may be shorter than that of the near memory cell group.

With the above-described verification operation, the near and far memory cell groups may be programmed to have different threshold voltage levels with respect to the same program state.

A subsequent read operation must correspond to all of the foregoing. Thus, at some later point, a read operation is directed to the previously programmed (target) memory cells (S140). Here again, the read operation will be performed as a function of memory cell grouping within the memory cell array.

For example, the read operation may discriminate memory cells on the basis of certain control voltages defined by the program verification operation (S120). Although the near and far memory cell groups have different threshold voltage levels with respect to the same program state, the read operation may be performed to be determined to be the same program state.

For example, the read operation may be performed such that different levels of read voltages are applied to the near and far memory cell groups. Since the near and far memory cell groups share the same word line, a read voltage may be applied to a word line plural times.

In other example embodiments, the read operation may be performed such that different levels of precharge voltages are applied to the near and far memory cell groups. A precharge voltage applied to the far memory cell group may be lower than a precharge voltage applied to the near memory cell group.

In still other example embodiments, the read operation may be performed such that different levels of common source line voltages are applied to the near and far memory cell groups. A common source line voltage applied to the far memory cell group may be higher than a common source line voltage applied to the near memory cell group.

In still other example embodiments, the read operation may be performed such that develop times of the near and far memory cell groups are different. A develop time of the far memory cell group may be shorter than that of the near memory cell group.

The above-described nonvolatile memory device and data processing method may be performed during a short program execution time. The reason may be that there is no need to apply a program voltage during a long time. Also, since a target program voltage level of a far cell is lower than that of a near cell, additional program loops for increasing a threshold voltage of a far cell may not be required. As the number of program loops decreases, a nonvolatile memory device may have reduced program time and program disturbance.

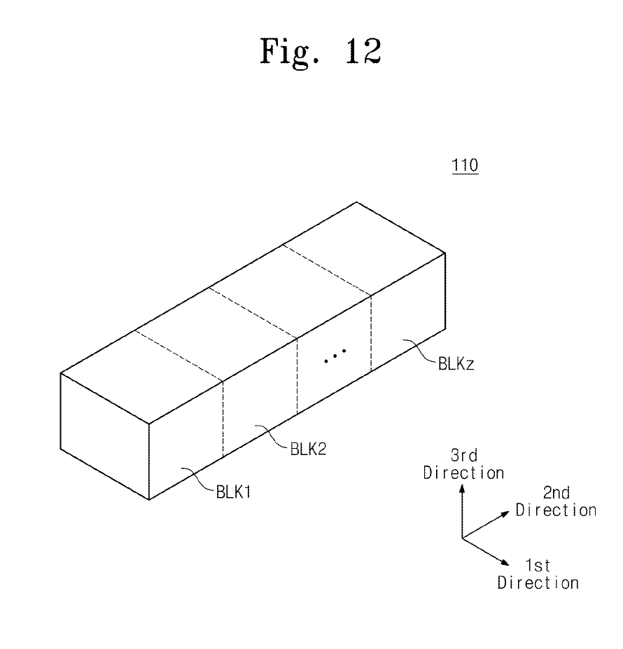

FIG. 12 is a diagram illustrating the memory cell array 110 of FIG. 1 according to certain embodiments of the inventive concept. Referring to FIG. 11, a memory cell array 110 may include a plurality of memory blocks BLK1 to BLKz, each of which is formed to have a three-dimensional structure (or, a vertical structure). For example, each of the memory blocks BLK1 to BLKz may include structures extending along first to third directions. Although not shown in FIG. 12, each of the memory blocks BLK1 to BLKz may include a plurality of cell strings extending along the second direction. Although not shown in FIG. 12, a plurality of cell strings may be spaced apart from one other along the first and third directions.

Cell strings (not shown) in one memory block may be coupled with a plurality of bit lines, a plurality of string selection lines, a plurality of word lines, one or more ground selection lines, and a common source line.

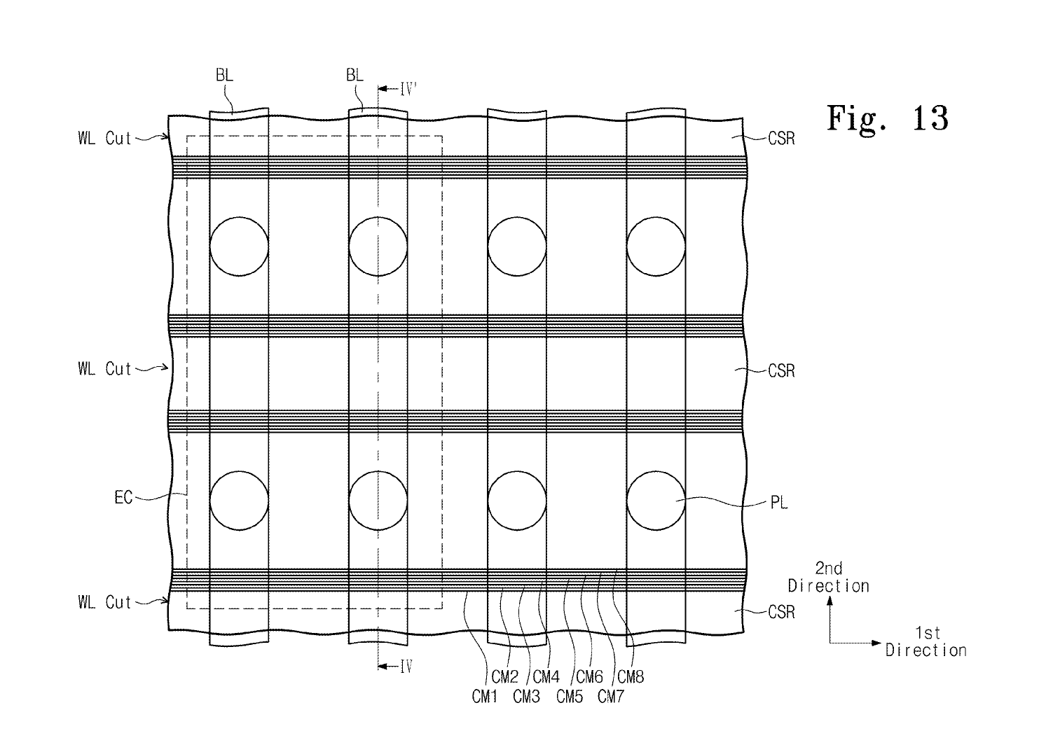

The plurality of memory blocks BLK1 to BLKz may be selected by an address decoder 120 in FIG. 1. For example, the address decoder 120 may be configured to select a memory block, corresponding to an input address ADDR, from among the plurality of memory blocks BLK1 to BLKz. Erasing, programming, and reading on the selected memory block may be made. The plurality of memory blocks BLK1 to BLKz will be more fully described with reference to FIGS. 13 to 16.

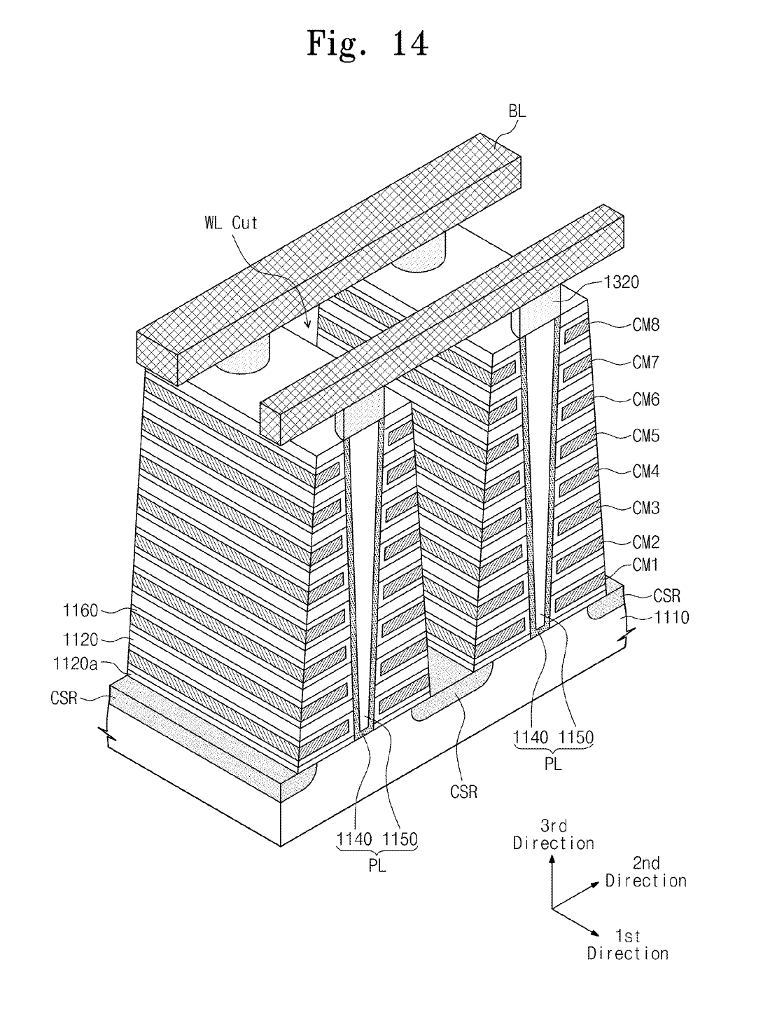

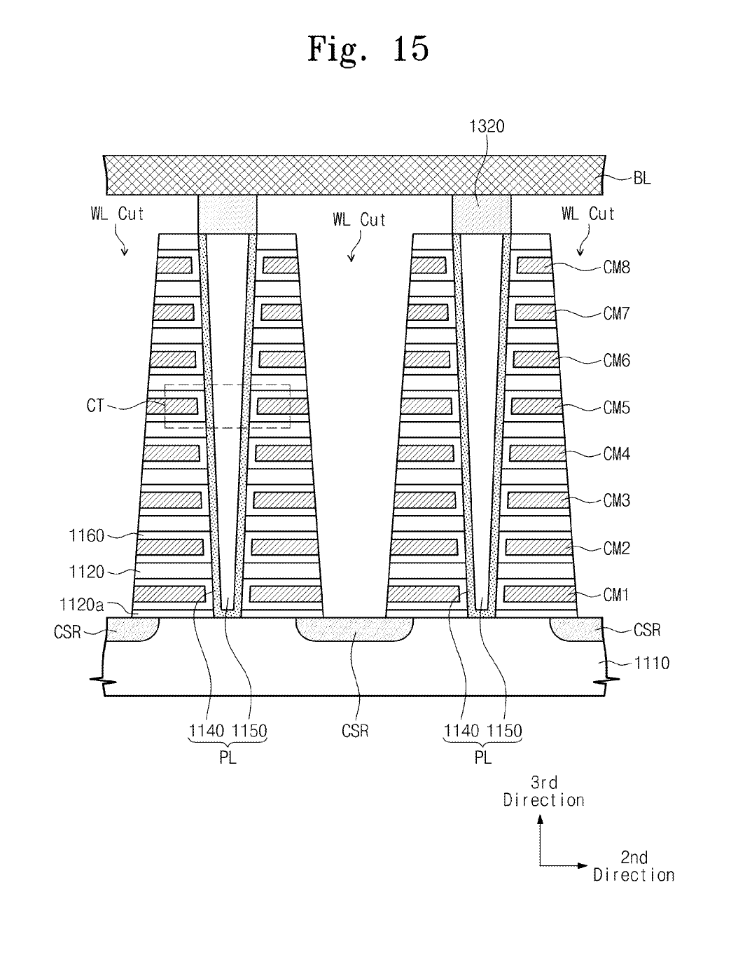

FIG. 13 is a top view of a portion of the one memory block of FIG. 12 according to an embodiment of the inventive concept. FIG. 14 is a perspective view taken along a line IV-IV′ in FIG. 13. FIG. 15 is a cross-sectional view taken along a line IV-IV′ in FIG. 13.

Referring to FIGS. 13, 14 and 15, three-dimensional structures extending along first to third directions may be provided.

A substrate 1110 may be provided. The substrate 1110 may be a well having a first conductivity type, for example. The substrate 1110 may be a p-well in which the Group III element such as boron is injected. The substrate 1110 may be a pocket p-well which is provided within an n-well. Below, it is assumed that the substrate 1110 is a p-well (or, a pocket p-well). However, the substrate 1110 is not limited to p-type.

A plurality of common source regions CSR extending along the first direction may be provided in the substrate 1110. The common source regions CSR may be spaced apart from one another along the second direction. The common source regions CSR may be connected in common to form a common source line.

The common source regions CSR may have a second conductivity type different from that of the substrate 1110. For example, the common source regions CSR may be n-type. Below, it is assumed that the common source regions CSR are the n-type. However, the common source regions CSR are not limited to the n-type.

Between two adjacent regions of the common source regions CSR, a plurality of insulation materials 1120 and 1120a may be provided sequentially on the substrate 1110 along the third direction (i.e., a direction perpendicular to the substrate 1110). The insulation materials 1120 and 1120a may be spaced apart along the third direction. The insulation materials 1120 and 1120a may extend along the first direction. For example, the insulation materials 1120 and 1120a may include an insulation material such as a semiconductor oxide film. The insulation material 1120a contacting with the substrate 1110 may be thinner in thickness than other insulation materials 1120.

Between two adjacent regions of the common source regions CSR, a plurality of pillars PL may be arranged sequentially along the first direction so as to penetrate the plurality of insulation materials 1120 and 1120a along the second direction. For example, the pillars PL may contact with the substrate 1110 through the insulation materials 1120 and 1120a.

In example embodiments, the pillars PL between two adjacent common source regions CSR may be spaced apart along the first direction. The pillars PL may be disposed in line along the first direction.

In example embodiments, the pillars PL may be formed of a plurality of materials, respectively. Each of the pillars PL may include a channel film 1140 and an inner material 1150 provided within the channel film 1140.

The channel films 1140 may include a semiconductor material (e.g., silicon) having a first conductivity type. For example, the channel films 1140 may include a semiconductor material (e.g., silicon) having the same type as the substrate 1110. The channel films 1140 can include intrinsic semiconductor being a nonconductor.

The inner materials 1150 may include an insulation material. For example, the inner materials 1150 may include an insulation material such as silicon oxide. Alternatively, the inner materials 1150 may include air gap.

Between two adjacent regions of the common source regions CSR, information storage films 1160 may be provided on exposed surfaces of the insulation materials 1120 and 1120a and the pillars PL. The information storage films 1160 may store information by trapping or discharging charges.

Between two adjacent common source regions CSR and between the insulation materials 1120 and 1120a, conductive materials CM1 to CM8 may be provided on exposed surfaces of the information storage films 1160. The conductive materials CM1 to CM8 may extend along the first direction. The conductive materials CM1 to CM8 on the common source regions CSR may be separated by word line cuts. The common source regions CSR may be exposed by the word line cuts. The word line cuts may extend along the first direction.

In example embodiments, the conductive materials CM1 to CM8 may include a metallic conductive material. The conductive materials CM1 to CM8 may include a nonmetallic conductive material such as polysilicon.

In example embodiments, information storage films 1160 provided on an upper surface of an insulation material placed at the uppermost layer among the insulation materials 1120 and 1120a can be removed. Exemplarily, information storage films, provided at sides opposite to the pillars PL, from among sides of the insulation materials 1120 and 1120a can be removed.

A plurality of drains 1320 may be provided on the plurality of pillars PL, respectively. The drains 1320 may include a semiconductor material (e.g., silicon) having a second conductivity type, for example. The drains 1320 may include an n-type semiconductor material (e.g., silicon). Below, it is assumed that the drains 1320 include n-type silicon. However, the prevent invention is not limited thereto. The drains 1320 can be extended to the upside of the channel films 114 of the pillars PL.

Bit lines BL extending in the second direction may be provided on the drains 1320 so as to be spaced apart from one another along the first direction. The bit lines BL may be coupled with the drains 1320. In example embodiments, the drains 1320 and the bit lines BL may be connected via contact plugs (not shown). The bit lines BL may include a metallic conductive material. Alternatively, the bit lines BL may include a nonmetallic conductive material such as polysilicon.

The conductive materials CM1 to CM8 may have first to eighth heights according to a distance from the substrate 1110.

The plurality of pillars PL may form a plurality of cell strings together with the information storage films 1160 and the plurality of conductive materials CM1 to CM8. Each of the pillars PL may form a cell string with information storage films 1160 and adjacent conductive materials CM1 to CM8.

The pillars PL may be provided on the substrate 1110 along row and column directions. The eighth conductive materials CM8 may constitute rows. Pillars connected with the eighth conductive material CM8 may constitute one row. The bit lines BL may constitute columns Pillars connected with the same bit line BL may constitute a column. The pillars PL may constitute a plurality of strings arranged along row and column directions together with the information storage films 1160 and the plurality of conductive materials CM1 to CM8. Each cell string may include a plurality of cell transistors CT stacked in a direction perpendicular to the substrate 1110.

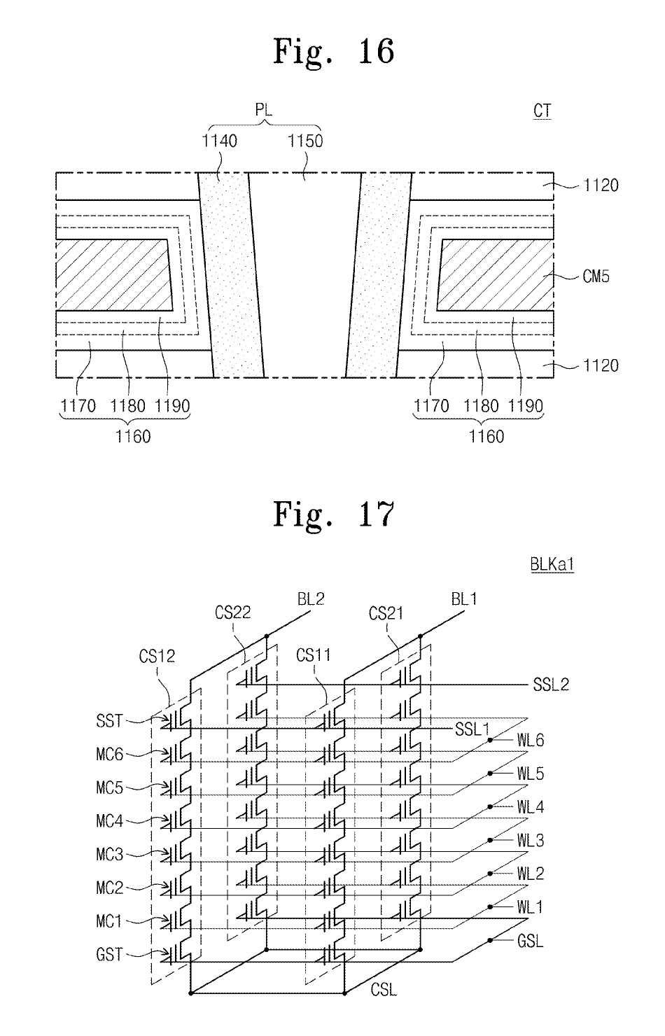

FIG. 16 is an enlarged view illustrating one of the cell transistors in FIG. 15. Referring to FIGS. 13 to 16, cell transistors CT may be formed of conductive materials CM1 to CM8, pillars PL, and information storage films 1160 provided between the conductive materials CM1 to CM8 and the pillars PL.

The information storage films 1160 may extend to upper surfaces and lower surfaces of the conductive materials CM1 to CM8 from regions between the conductive materials CM1 to CM8 and the pillars PL. Each of the information storage films 1160 may include first to third sub insulation films 1170, 1180, and 1190.

In the cell transistors CT, the channel films 1140 of the pillars PL may include the same p-type silicon as the substrate 1110. The channel films 1140 may act as bodies of cell transistors CT. The channel films 1140 may be formed in a direction perpendicular to the substrate 1110. The channel films 1140 of the pillars PL may act as a vertical body. Vertical channels may be formed at the channel films 1140.

The first sub insulation films 1170 adjacent to the pillars PL may act as tunneling insulation films of the cell transistors CT. For example, the first sub insulation films 1170 may include a thermal oxide film, respectively. The first sub insulation films 1170 may include a silicon oxide film, respectively.

The second sub insulation films 1180 may act as charge storage films of the cell transistors CT. For example, the second sub insulation films 1180 may act as a charge trap film, respectively. For example, the second sub insulation films 1180 may include a nitride film or a metal oxide film, respectively.

The third sub insulation films 1190 adjacent to the conductive materials CM1 to CM8 may act as blocking insulation films of the cell transistors CT. In example embodiments, the third sub insulation films 1190 may be formed of a single layer or multiple layers. The third sub insulation films 1190 may be a high dielectric film (e.g., an aluminum oxide film, a hafnium oxide film, etc.) having a dielectric constant larger than those of the first and second sub insulation films 1170 and 1180. The third sub insulation films 1190 may include a silicon oxide film, respectively.

In example embodiments, the first to third sub insulation films 1170 to 1190 may constitute ONA (oxide-nitride-aluminum-oxide) or ONO (oxide-nitride-oxide).

The plurality of conductive materials CM1 to CM8 may act as a gate (or, a control gate), respectively.

That is, the plurality of conductive materials CM1 to CM8 acting as gates (or, control gates), the third sub insulation films 1190 acting as block insulation films, the second sub insulation films 1180 acting as charge storage films, the first sub insulation films 1170 acting as tunneling insulation films, and the channel films 1140 acting as vertical bodies may constitute a plurality of cell transistors CT stacked in a direction perpendicular to the substrate 1110. Exemplarily, the cell transistors CT may be a charge trap type cell transistor.

The cell transistors CT can be used for different purposes according to height. For example, among the cell transistors CT, cell transistors having at least one height and placed at an upper portion may be used as string selection transistors. The string selection transistors may be configured to perform switching operations between cell strings and bit lines. Among the cell transistors CT, cell transistors having at least one height and placed at a lower portion may be used as ground selection transistors. The ground selection transistors may be configured to perform switching operations between cell strings and a common source line formed of common source regions CSR. Cell transistors between cell transistors used as string and ground selection transistors may be used as memory cells and dummy memory cells.

The conductive materials CM1 to CM8 may extend along the first direction to be connected with the plurality of pillars PL. The conductive materials CM1 to CM8 may constitute conductive lines interconnecting cell transistors CT of the pillars PL. In example embodiments, the conductive materials CM1 to CM8 may be used as a string selection line, a ground selection line, a word line, or a dummy word line according to the height.

Conductive lines interconnecting cell transistors used as string selection transistors may be used as string selection lines. Conductive lines interconnecting cell transistors used as ground selection transistors may be used as ground selection lines. Conductive lines interconnecting cell transistors used as memory cells may be used as word lines. Conductive lines interconnecting cell transistors used as dummy memory cells may be used as dummy word lines.

FIG. 17 is an equivalent circuit for the part EC of a top view in FIG. 13 according to an embodiment of the inventive concept. Referring to FIGS. 13 to 17, cell strings CS11, CS12, CS21, and CS22 may be provided between bit lines BL1 and BL2 and a common source line CSL. Cell strings CS11 and CS21 may be connected between the first bit line BL1 and the common source line CSL, and cell strings CS12 and CS22 may be connected between the second bit line BL2 and the common source line CSL.

Common source regions CSR may be connected in common to form a common source line CSL.

The cell strings CS11, CS12, CS21, and CS22 may correspond to four pillars of a part EC of a top view in FIG. 13. The four pillars may constitute four cell strings CS11, CS12, CS21, and CS22 together with conductive materials CM1 to CM8 and information storage films 116.

In example embodiments, the first conductive materials CM1 may constitute ground selection transistors GST with the information storage films 1160 and the pillars PL. The first conductive materials CM 1 may form a ground selection line GSL. The first conductive materials CM1 may be interconnected to form a ground selection line GSL.

The second to seventh conductive materials CM2 to CM7 may constitute first to sixth memory cells MC 1 to MC6 with the information storage films 1160 and the pillars PL. The second to seventh conductive materials CM2 to CM7 may be used as second to sixth word lines WL2 to WL6.

The second conductive material CM2 may be interconnected to form the first word line WL1. The third conductive material CM3 may be interconnected to form the second word line WL2. The fourth conductive material CM4 may be interconnected to form the third word line WL3. The fifth conductive material CM5 may be interconnected to form the fourth word line WL4. The sixth conductive material CM6 may be interconnected to form the fifth word line WL5. The seventh conductive material CM7 may be interconnected to form the sixth word line WL6.

The eighth conductive materials CM8 may constitute string selection transistors SST with the information storage films 1160 and the pillars PL. The eighth conductive materials CM8 may form string selection lines SSL1 and SSL2.

Memory cells of the same height may be connected in common with one word line. Accordingly, when applied to a word line of a specific height, a voltage may be applied to all cell strings CS11, CS12, CS21, and CS22.

Cell strings in different rows may be connected with different string selection lines SSL1 and SSL2, respectively. The cell strings CS11, CS12, CS21, and CS22 may be selected or unselected by the row by selecting or unselecting the string selection lines SSL1 and SSL2. For example, cell strings (CS11 and CS12) or (CS21 and CS22) connected with an unselected string selection line SSL1 or SSL2 may be electrically separated from the bit lines BL1 and BL2. Cell strings (CS21 and CS22) or (CS11 and CS12) connected with a selected string selection line SSL2 or SSL1 may be electrically connected with the bit lines BL1 and BL2.

The cell strings CS11, CS12, CS21, and CS22 may be connected with the bit lines BL1 and BL2 by the column The cell strings CS11 and CS21 may be connected with the bit line BL1, and the cell strings CS12 and CS22 may be connected with the bit line BL2. The cell strings CS11, CS12, CS21, and CS22 may be selected and unselected by the column by selecting and unselecting the bit lines BL1 and BL2.

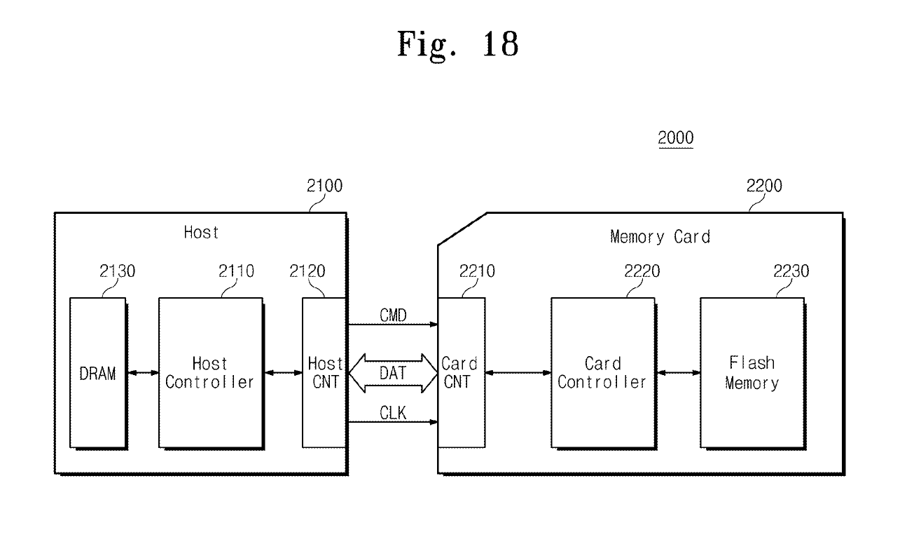

FIG. 18 is a block diagram illustrating a memory card system that may incorporate a nonvolatile memory device according to an embodiment of the inventive concept. A memory card system 2000 may include a host 2100 and a memory card 2200. The host 2100 may include a host controller 2110, a host connection unit 2120, and a DRAM 2130.

The host 2100 may write data at the memory card 2200 and read data from the memory card 2200. The host controller 2110 may send a command (e.g., a write command), a clock signal CLK generated from a clock generator (not shown) in the host 2100, and data to the memory card 2200 via the host connection unit 2120. The DRAM 2130 may be a main memory of the host 2100.

The memory card 2200 may include a card connection unit 2210, a card controller 2220, and a flash memory 2230. The card controller 2220 may store data at the flash memory 2230 in response to a command input via the card connection unit 2210. The data may be stored in synchronization with a clock signal generated from a clock generator (not shown) in the card controller 2220. The flash memory 2230 may store data transferred from the host 2100. For example, in a case where the host 2100 is a digital camera, the memory card 2200 may store image data.

In the memory card system 2000 of FIG. 18, a target program voltage may vary according to a distance from a program voltage source at a data programming operation of the flash memory 2230. A program operation of the memory card system 2000 may be performed during a short program execution time. Also, as the number of program loops for programming decreases, the memory card system 2000 may have reduced program time and program disturbance.

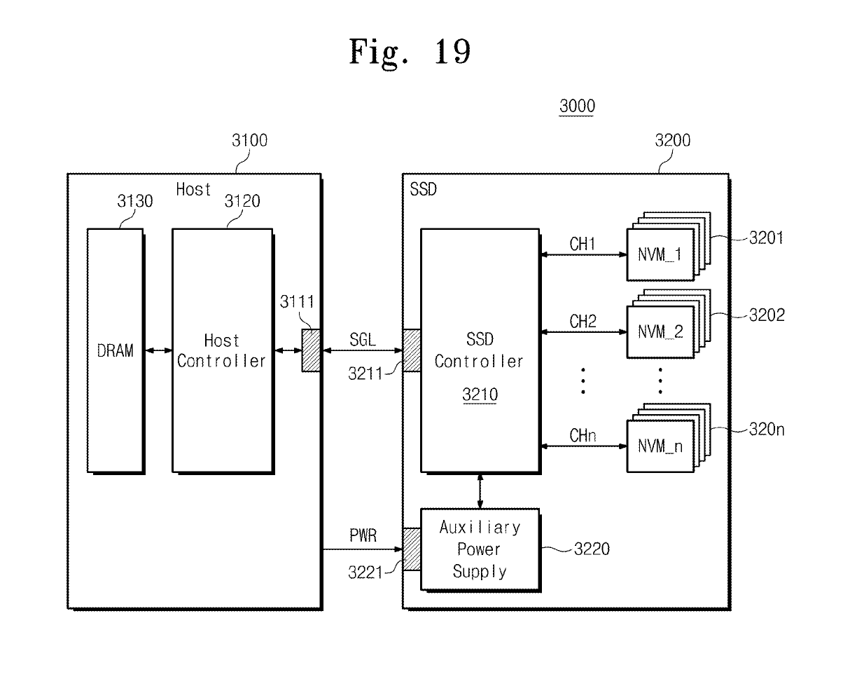

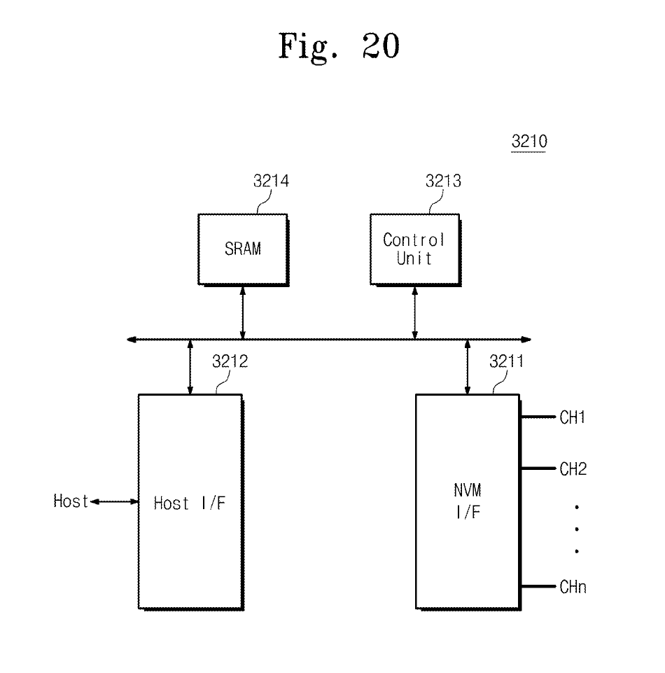

FIG. 19 is a block diagram illustrating a solid state drive (SSD) system that may incorporate a memory device according to the inventive concept is applied. Referring to FIG. 19, a solid state drive (SSD) system 3000 may include a host 3100 and an SSD 3200. The host 3100 may include a host interface 3111, a host controller 3120, and a DRAM 3130.

The host 3100 may write data in the SSD 3200 or read data from the SSD 3100. The host controller 3120 may transfer signals SGL such as a command, an address, a control signal, and the like to the SSD 3200 via the host interface 3111. The DRAM 3130 may be a main memory of the host 3100.

The SSD 3200 may exchange signals SGL with the host 3100 via the host interface 3211, and may be supplied with a power via a power connector 3221. The SSD 3200 may include a plurality of nonvolatile memories 3201 to 320n, an SSD controller 3210, and an auxiliary power supply 3220. Herein, the nonvolatile memories 3201 to 320n may be implemented by not only a NAND flash memory but also nonvolatile memories such as PRAM, MRAM, ReRAM, and so on.

The plurality of nonvolatile memories 3201 to 320n may be used as a storage medium of the SSD 3200. The plurality of nonvolatile memories 3201 to 320n may be connected with the SSD controller 3210 via a plurality of channels CH1 to CHn. One channel may be connected with one or more nonvolatile memories. Nonvolatile memories connected with one channel may be connected with the same data bus.

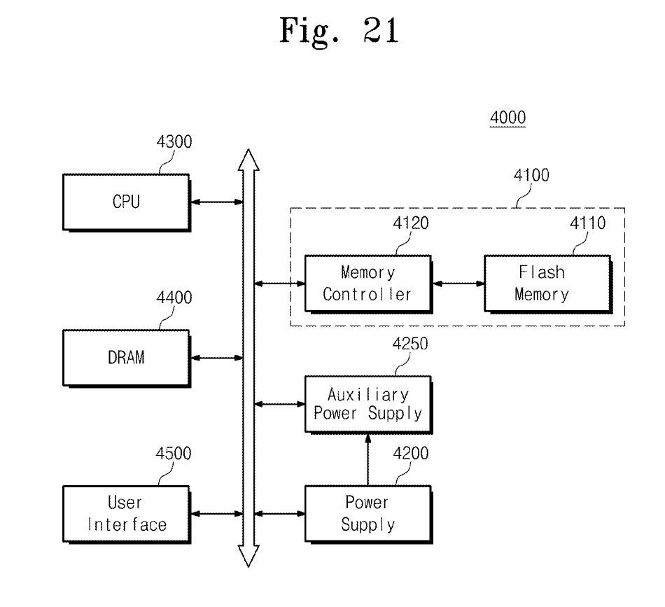

The SSD controller 3210 may exchange signals SGL with the host 3100 via the host interface 3211. Herein, the signals SGL may include a command, an address, data, and the like. The SSD controller 3210 may be configured to write or read out data to or from a corresponding nonvolatile memory according to a command of the host 3100. The SSD controller 3210 will be more fully described with reference to FIG. 20.

The auxiliary power supply 3220 may be connected with the host 3100 via the power connector 3221. The auxiliary power supply 3220 may be charged by a power PWR from the host 3100. The auxiliary power supply 3220 may be placed inside or outside the SSD 3200. For example, the auxiliary power supply 3220 may be put on a main board to supply an auxiliary power to the SSD 3200.

FIG. 20 is a block diagram further illustrating the SSD controller 3210 of FIG. 19. Referring to FIG. 20, the SSD controller 3210 may include an NVM interface 3211, a host interface 3212, an encryption circuit 3213, a control unit 3214, and an SRAM 3215.

The NVM interface 3211 may scatter data transferred from a main memory of a host 3100 to channels CH1 to CHn, respectively. The NVM interface 3211 may transfer data read from nonvolatile memories 3201 to 320n to the host 3100 via the host interface 3212.

The host interface 3212 may provide an interface with an SSD 3200 according to the protocol of the host 3100. The host interface 3212 may communicate with the host 3100 using USB (Universal Serial Bus), SCSI (Small Computer System Interface), PCI express, ATA, PATA (Parallel ATA), SATA (Serial ATA), SAS (Serial Attached SCSI), or the like. The host interface 3212 may also perform a disk emulation function which enables the host 3100 to recognize the SSD 3200 as a hard disk drive (HDD).

The control unit 3214 may analyze and process signals input from the host 3100. The control unit 3214 may control the host 3100 or the nonvolatile memories 3201 to 320n through the host interface 3212 or the NVM interface 3211. The control unit 3214 may control the nonvolatile memories 3201 to 320n according to firmware to drive the SSD 3200.

The SRAM 3215 may be used to drive software which efficiently manages the nonvolatile memories 3201 to 320n. The SRAM 3215 may store metadata input from a main memory of the host 3100 or cache data. At a sudden power-off operation, metadata or cache data stored in the SRAM 3215 may be stored in the nonvolatile memories 3201 to 320n using an auxiliary power supply 3220.

In the SSD system 3000 of FIG. 19, a target program voltage may vary according to a distance from a program voltage source at a data programming operation of the nonvolatile memories 3201 to 320n. A program operation of the SSD system 3000 may be performed during a short program execution time. Also, as the number of program loops for programming decreases, the SSD system 3000 may have reduced program time and program disturbance.

SRAM 3214 in FIGS. 19 and 20 may be replaced with a nonvolatile memory. For example, the SSD system 3000 according to another embodiment of the inventive concept may be implemented such that nonvolatile memories such as flash memory, PRAM, RRAM, MRAM, and so on perform a role of the SRAM 3214.

FIG. 21 is a block diagram illustrating an electronic device that may include a memory system according to an embodiment of the inventive concept. Herein, an electronic device 4000 may be a personal computer or a handheld electronic device such as a notebook computer, a cellular phone, a PDA, a camera, or the like.

Referring to FIG. 21, the electronic device 4000 may include a memory system 4100, a power supply device 4200, an auxiliary power supply 4250, a CPU 4300, a DRAM 4400, and a user interface 4500. The memory system 5100 may include a flash memory 5110 and a memory controller 5120. The memory system 4100 can be built in the electronic device 4000.

As described above, in the electronic device 4000 of FIG. 20, a target program voltage may vary according to a distance from a program voltage source at a data programming operation of the flash memory 4110. A program operation of the electronic device 4000 may be performed during a short program execution time. Also, as the number of program loops for programming decreases, the electronic device 4000 may have reduced program time and program disturbance.

The inventive concept may be modified or changed variously. For example, control logic and a page buffer may be changed or modified variously according to environment and use.

While the inventive concept has been described with reference to exemplary embodiments, it will be apparent to those skilled in the art that various changes and modifications may be made without departing from the scope of the present inventive concept as defined by the following claims. Therefore, it should be understood that the above embodiments are not limiting, but illustrative.

What is claimed is:

1. A nonvolatile memory device comprising:
a memory cell array designating a first memory cell group including first memory cells connected with a word line and disposed less than a reference distance from a word line voltage source in a word line direction, and a second memory cell group including second memory cells connected to the word line and disposed more than the reference distance from the word line voltage source in the word line direction; and
control logic configured during a data processing operation to provide a first word line voltage to a first target memory cell among the first memory cells, and a second word line voltage different from the first word line voltage to a second target memory cell among the second memory cells.

2. The nonvolatile memory device of claim 1, wherein the data processing operation is a program verification operation, and the first and second word line voltages are respective program verification voltages, wherein the first word line voltage is greater than the second word line voltage.

3. The nonvolatile memory device of claim 1, wherein the data processing operation is a read operation, and the first and second word line voltages are read voltages, wherein the first word line voltage is greater than the second word line voltage.

4. The nonvolatile memory device of claim 1, wherein the word line voltage source is a row address decoder.

5. The nonvolatile memory device of claim 1, wherein the memory cell array has a three-dimensional structure.

6. The nonvolatile memory device of claim 1, further comprising:
a first bit line connected with at least one of the first memory cells, and a second bit line connected with at least one of the second memory cells; and
a page buffer unit having a first page buffer unit connected to the first bit line and a second page buffer unit connected to the second bit line, wherein the first and second page buffer units operate independently during the data processing operation in response to a control signal from the control logic indicating one of the first target memory cell and the second target memory cell.

7. A nonvolatile memory device comprising:
a memory cell array designating a first memory cell group including first memory cells connected with a word line and disposed less than a reference distance from a word line voltage source in a word line direction, and a second memory cell group including second memory cells connected to the word line and disposed more than the reference distance from the word line voltage source in the word line direction;
a first bit line group connected with memory cells of the first memory cell group, and a second bit line group connected with memory cells of the second memory cell group; and
control logic configured to provide a first precharge voltage to the first bit line group and a second precharge voltage having a level different from the first precharge voltage to the second bit line group during a data processing operation.

8. The nonvolatile memory device of claim 7, wherein the word line voltage source is a row address decoder.

9. The nonvolatile memory device of claim 7, wherein during the data processing operation the first precharge voltage is higher than the second precharge voltage.

10. The nonvolatile memory device of claim 9, wherein the data processing operation is one of a read operation and a program verification operation.

11. The nonvolatile memory device of claim 10, further comprising:
a first voltage generator providing the first precharge voltage; and
a second voltage generator separate from the first voltage generator providing the second precharge voltage.

12. A nonvolatile memory device comprising:
a memory cell array designating a first memory cell group including first memory cells connected with a word line and disposed less than a reference distance from a word line voltage source in a word line direction, and a second memory cell group including second memory cells connected to the word line and disposed more than the reference distance from the word line voltage source in the word line direction;
a first bit line group connected with memory cells of the first memory cell group, and a second bit line group connected with memory cells of the second memory cell group;
a data input/output (I/O) unit connected with the first bit line group and the second bit line group; and
control logic configured to control the data I/O unit during a data processing operation to define a first sensing time for the first bit line group and a second sensing time for the second bit line group, wherein the first and second sensing times are different.

13. The nonvolatile memory device of claim 12, wherein the data processing operation is one of a read operation and a program verification operation.

14. The nonvolatile memory device of claim 13, wherein the first sensing time is longer than the second sensing time.

15. A nonvolatile memory device comprising:
a memory cell array designating a first memory cell group including first memory cells connected with a word line and disposed less than a reference distance from a word line voltage source in a word line direction, and a second memory cell group including second memory cells connected to the word line and disposed more than the reference distance from the word line voltage source in the word line direction;
at least one common source line driver connected with the memory cells in the first and second memory cell groups and configured to provide a common source line voltage; and
control logic configured to control the at least one common source line (CSL) driver during a data processing operation to define a first CSL voltage provided to the first bit line group and a second CSL voltage provided to the second bit line group, wherein the first and second CSL voltages are different.

16. The nonvolatile memory device of claim 15, wherein the data processing operation is one of a read operation and a program verification operation.

17. The nonvolatile memory device of claim 16, wherein the at least one CSL driver comprises:
a first CSL driver configured to provide the first CSL voltage to the first memory cell group; and
a second CSL driver independently operating in response to the control logic from the first CSL driver and configured to provide a CSL voltage to the second memory cell group.

18. The nonvolatile memory device of claim 17, wherein during the data processing operation, the first CSL voltage is lower than the second CSL voltage.

19. A nonvolatile memory device comprising:
a memory cell array designating a first memory cell group including first memory cells connected with a word line and disposed less than a reference distance from a word line voltage source in a word line direction, and a second memory cell group including second memory cells connected to the word line and disposed more than the reference distance from the word line voltage source in the word line direction;
a data input/output (I/O) unit configured to provide program data to memory cell in both the first and second memory cell groups; and
control logic configured during a data processing operation to define a first lower limit value for a first threshold voltage distribution associated with a program state for memory cells of the first memory cell group, and a second lower limit value for a second threshold voltage distribution associated with the program state for memory cells of the second memory cell group, wherein the first and second threshold voltage distributions are different and the first and second lower limit values are different.

20. The nonvolatile memory device of claim 19, wherein the data processing operation is a program verification operation, the first lower limit value is used to discriminate memory cells in the first memory cell group programmed to the program state, and the second lower limit value is used to discriminate memory cells in the second memory cell group programmed to the program state, the first lower limit value being higher than the second lower limit value.

21. The nonvolatile memory device of claim 19, wherein the data processing operation is a read operation, the first lower limit value is used to discriminate memory cells in the first memory cell group programmed to the program state, and the second lower limit value is used to discriminate memory cells in the second memory cell group programmed to the program state, the first lower limit value being higher than the second lower limit value.
